(19) United States
(12) Patent Application Publication
(10) Pub. No.: US 2025/0120157 A1
(43) Pub. Date: Apr. 10, 2025

(54) SEMICONDUCTOR DEVICE WITH SLANTED FIELD PLATE

(71) Applicant: TEXAS INSTRUMENTS INCORPORATED, Dallas, TX (US)

(72) Inventors: Jonas Höhenberger, Kissing (DE); Ujwal Radhakrishna, San Jose, CA (US); Michael Lueders, Freising (DE); Meng-Chia Lee, Allen, TX (US); Chang Soo Suh, Allen, TX (US); Zhikai Tang, Sunnyvale, CA (US); Jungwoo Joh, Allen, TX (US); Timothy Bryan Merkin, Princeton, TX (US); Stefan Herzer, Marzling (DE); Bernhard Ziegltrum, Freising (DE); Helmut Rinck, Gammelsdorf (DE); Michael Hans Enzelberger-Heim, Munich (DE); Ercuement Hasanoglu, Augsburg (DE)

(21) Appl. No.: 18/610,150

(22) Filed: Mar. 19, 2024

Related U.S. Application Data
(60) Provisional application No. 63/589,040, filed on Oct. 10, 2023.

(51) Int. Cl. H01L 29/40; H01L 21/027; H01L 21/311; H01L 29/20; H01L 29/66; H01L 29/778

(52) U.S. Cl. CPC H10D 64/111; H01L 21/0274; H01L 21/31144; H10D 30/015; H10D 30/475; H10D 62/8503; H10D 64/01

(57) ABSTRACT

The present disclosure generally relates to a semiconductor device having a slanted field plate. In an example, a semiconductor device includes a semiconductor substrate, a gate, a drain contact, a source contact, and a field plate. The gate is on a surface of the semiconductor substrate. The drain contact and a source contact are on the semiconductor substrate. The field plate is over the surface of the semiconductor substrate and extends from one side of the gate towards the drain contact. The field plate includes multiple field plate portions. Each of the multiple field plate portions has a uniform respective slope with respect to the surface, and the multiple field plate portions have different slopes.

### CROSS-REFERENCE TO RELATED APPLICATIONS

This application claims priority to and the benefit of U.S. Provisional Patent Application Ser. No. 63/589,040, filed on Oct. 10, 2023, which is incorporated herein by reference in its entirety.

### BACKGROUND

A type of semiconductor device is a high electron mobility transistor (HEMT). A HEMT typically employs different semiconductor materials to form a heterojunction, where a channel may be formed near the heterojunction and between a source and a drain. A HEMT may have a high speed operation, which makes HEMTs attractive for high frequency applications, among others.

### SUMMARY

This Summary is provided to introduce a brief selection of disclosed concepts in a simplified form that are further described below in the Detailed Description including the drawings provided. Various disclosed devices and methods may be beneficially applied to a semiconductor device having a slanted field plate. While such embodiments may be expected to achieve reduced peak electric field, increased electric field curve, improved gate time-dependent dielectric breakdown (TDDB), increased breakdown voltage (BV), and/or reduced gate-drain capacitance and leakage current, no particular result is a requirement unless explicitly recited in a particular claim.

An example described herein is a semiconductor device. The semiconductor device includes a semiconductor substrate, a gate, a drain contact, a source contact, and a field plate. The gate is on a surface of the semiconductor substrate. The drain contact and a source contact are on the semiconductor substrate. The field plate is over the surface of the semiconductor substrate and extends from one side of the gate towards the drain contact. The field plate includes multiple field plate portions. Each of the multiple field plate portions has a uniform respective slope with respect to the surface, and the multiple field plate portions have different slopes.

Another example is a method. An etch stop layer is formed on a surface of a semiconductor substrate of a semiconductor device. The semiconductor device includes a gate, a drain contact, and a source contact on the surface. One or more dielectric layers are formed on the etch stop layer. One or more photoresist layers are formed on the dielectric layer between the gate and the drain contact. One or more photoresist layers are patterned with one or more grayscale masks to form first multiple slanted surfaces. Each first slanted surface has a respective uniform slope, and the first slanted surfaces have different slopes. The one or more dielectric layers are etched to form second multiple slanted surfaces based on the first slanted surfaces of the one or more photoresist layers and to expose part of the etch stop layer. A field plate having multiple field plate portions is formed on the second multiple slanted surfaces and on the exposed part of the etch stop layer between the gate and the drain contact. Each of the multiple field plate portions has a uniform respective slope with respect to the surface of the semiconductor substrate, and the multiple field plates have different slopes.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

FIG. 1 is a schematic illustrating a cross-sectional diagram of a high electron mobility transistor (HEMT) that includes field plates, according to some examples.

FIG. 2 is a schematic illustrating a circuit representing the HEMT of FIG. 1, according to some examples.

FIGS. 3A and 3B are graphs illustrating distributions of an electric field in a substrate of a HEMT, according to some examples.

FIGS. 4A and 4B are graphs illustrating distributions of an electric field in a substrate of a HEMT, according to some examples.

FIGS. 5A and 5B are graphs illustrating distributions of an electric field in a substrate of a HEMT, according to some examples.

FIG. 6 includes a schematic illustrating a HEMT including multiple leveled field plates and a graph illustrating distributions of an electric field in a substrate of the HEMT, according to some examples.

FIG. 7 includes a schematic illustrating a HEMT including a single-sided slanted gate field plate and a graph illustrating distributions of an electric field in a substrate of the HEMT, according to some examples.

FIG. 8 includes a schematic illustrating a HEMT including a single-sided slanted gate field plate with multiple slopes and a graph illustrating distributions of an electric field in a substrate of the HEMT, according to some examples.

FIG. 9 includes a schematic illustrating a HEMT including a single-sided slanted source field plate with multiple slopes and a graph illustrating distributions of an electric field in a substrate of the HEMT, according to some examples.

FIGS. 10, 11, and 12 are schematics illustrating aspects of grayscale photolithography and an etch process for forming a slanted field plate, according to some examples.

FIGS. 13 and 14 are schematics illustrating additional aspects of grayscale photolithography and an etch process, according to some examples.

FIGS. 15 and 16 are schematics illustrating aspects of masks that may be implemented in grayscale photolithography, according to some examples.

FIG. 17 is a flowchart of a method of manufacturing a semiconductor device according to some examples.

FIGS. 18, 19, 20, 21, 22, 23, 24, 25, 26, 27, 28 and 29 are schematics illustrating cross-sectional views of the semiconductor device at various stages of manufacturing in the method of FIG. 17, according to some examples.

FIGS. 30A and 30B are a flowchart of a method of manufacturing a semiconductor device according to some examples.

FIGS. 31, 32, 33, and 34 are schematics illustrating cross-sectional views of the semiconductor device at various stages of manufacturing in the method of FIGS. 30A and 30B, according to some examples.

FIGS. 35A and 35B are a flowchart of a method of manufacturing a semiconductor device according to some examples.

FIGS. 36, 37, 38, 39, 40, 41, and 42 are schematics illustrating cross-sectional views of the semiconductor device at various stages of manufacturing in the method of FIGS. 35A and 35B, according to some examples.

FIGS. 43A and 43B are a flowchart of a method of manufacturing a semiconductor device according to some examples.

FIGS. 44, 45, 46, 47, 48, and 49 are schematics illustrating cross-sectional views of the semiconductor device at various stages of manufacturing in the method of FIGS. 43A and 43B, according to some examples.

FIGS. 50A and 50B are a flowchart of a method of manufacturing a semiconductor device according to some examples.

FIGS. 51, 52, 53, 54, 55, and 56 are schematics illustrating cross-sectional views of the semiconductor device at various stages of manufacturing in the method of FIGS. 50A and 50B, according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to a semiconductor device having a slanted field plate. In some examples described herein, the semiconductor device is a high electron mobility transistor (HEMT). The semiconductor device may have one or multiple field plates. A field plate may have one or multiple slanted field plate portions with respective slopes, which may be different for different slanted field plate portions. A field plate may have different configurations, such as having different surfaces like convex or concave surfaces, in other examples. In some examples, a field plate may be formed on a dielectric structure that is patterned using a grayscale photolithography process. Various examples of field plates described herein may achieve reduced peak electric field, increased electric field curve, improved gate time-dependent dielectric breakdown (TDDB), increased breakdown voltage (BV), and/or reduced gate-drain capacitance and leakage current. Other benefits and advantages may be achieved.

Various examples are described herein. Although the specific examples may illustrate various aspects of the above generally described features, examples may incorporate any combination of features described in detail in examples below. Some cross-sectional views of various semiconductor devices herein may be general depictions to communicate various aspects or concepts concerning such semiconductor devices. More specifically, some field plates and semiconductor devices illustrated in cross-sectional views may not necessarily accurately depict a structure of such field plates and semiconductor devices, except to the extent described herein. The illustrations of those field plates and semiconductor devices is to communicate various aspects or concepts concerning those field plates and semiconductor devices.

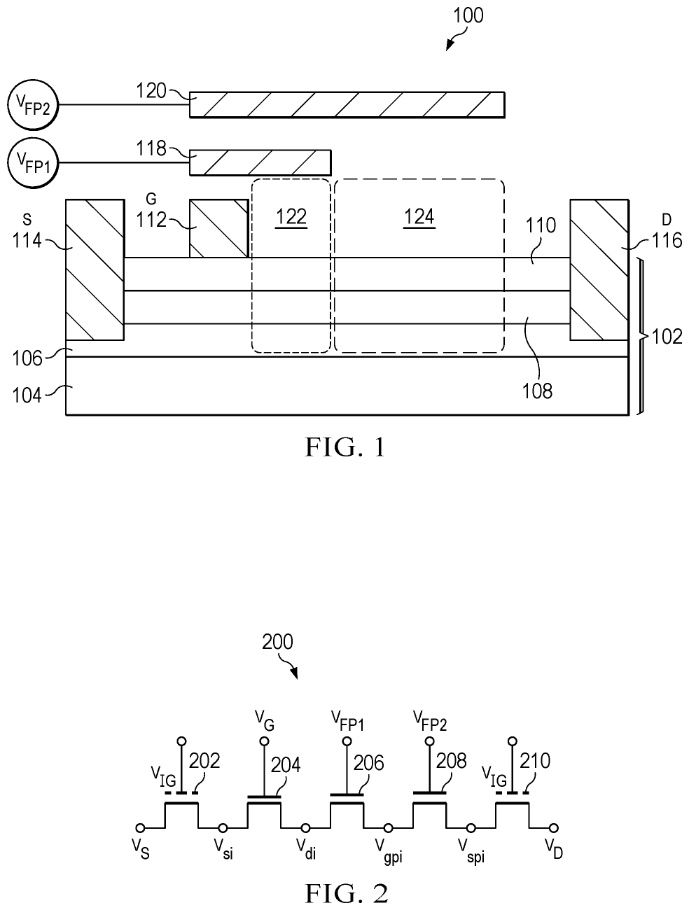

In a high electron mobility transistor (HEMT), one or more field plates can manage electric fields between the source and drain of the HEMT when the HEMT is turned off to increase the break down voltage (BV). FIG. 1 illustrates an example HEMT 100 that includes field plates. The HEMT 100 is on and/or in a semiconductor substrate 102. The semiconductor substrate 102 includes a support substrate 104, one or more transition layers 106 on or over the support substrate 104, a channel layer 108 on or over the transition layer(s) 106, and a barrier layer 110 on or over the channel layer 108. Examples of such layers are described in more detail subsequently. A gate layer 112 is on or over the barrier layer 110. The channel layer 108, barrier layer 110, and gate layer 112 may each be gallium nitride-based materials, as described in subsequent examples. A source contact 114 is electrically coupled to a source of the HEMT 100, and a drain contact 116 is electrically coupled to a drain of the HEMT 100. The contacts 114, 116, as illustrated, extend through the barrier layer 110 and channel layer 108 into the transition layer(s) 106 and are on/over the support substrate 104. In some examples, the contacts 114, 116 may contact and/or extend into, but not extend through, the barrier layer 110. In some examples, the contacts 114, 116 may extend through the barrier layer 110 and may contact and/or extend into, but not extend through, the channel layer 108. The gate layer 112 is laterally between the source contact 114 and the drain contact 116. A channel of the HEMT 100 underlies the gate layer 112 in the channel layer 108 and is laterally between the source and the drain, both of which are in the channel layer 108. In some examples, the HEMT 100 is an enhancement mode (E-mode) device.

The HEMT 100 further includes a first field plate 118 and a second field plate 120. The first field plate 118 is over the gate layer 112 and extends laterally from the gate layer 112 toward the drain contact 116. The second field plate 120 is over the first field plate 118 and the gate layer 112 and extends laterally from the gate layer 112 toward the drain contact 116 a greater distance than the first field plate 118. In various examples, multiple field plates may be formed over the barrier layer between the source and drain.

In operation, a first field plate voltage (V_{FP1}) is applied to the first field plate 118, and a second field plate voltage (V_{FP2}) is applied to the second field plate 120. The first field plate voltage (V_{FP1}) may be a different voltage from the second field plate voltage (V_{FP2}) to provide different electric fields by the field plates 118, 120. In some examples, the first field plate voltage (V_{FP1}) may be the voltage applied to the gate layer 112 (e.g., the first field plate 118 may be electrically coupled to the gate layer 112), and the second field plate voltage (V_{FP2}) may be the voltage applied to the source (e.g., the second field plate 120 may be electrically coupled to the source contact 114).

A region 122 of the HEMT 100 under the first field plate 118 and next to the gate layer 112 may form a first field plate transistor, and a region 124 of the HEMT 100 under the second field plate 120 that extends laterally beyond the first field plate 118 may form a second field plate transistor. Each field plate transistor may be a depletion mode (D-mode) device with a negative threshold voltage.

FIG. 2 is a circuit 200 representing the HEMT 100. The circuit 200 includes access transistors 202, 210, a core transistor 204, a first field plate transistor 206, and a second field plate transistor 208. The core transistor 204 is the HEMT formed by the gate layer 112, source, channel, and drain in the HEMT 100, and can be controlled by the gate voltage V_{G}. The first field plate transistor 206 is the HEMT formed with the first field plate 118, and the second field plate transistor 208 is the HEMT formed with the second field plate 120. Access transistors 202 and 210 represent transistors formed in access regions, including gate-source and gate-drain regions, where the channel is not covered by either gate of field plates. The source of the access transistor 202 is the source of the HEMT 100. The drain of the access transistor 202 is electrically coupled with the source of the core transistor 204. The drain of the core transistor 204 is electrically coupled with the source of the first field plate transistor 206. The drain of the first field plate transistor 206 is electrically coupled with the source of the second field plate transistor 208. The drain of the second field plate transistor 208 is electrically coupled with the source of the access transistor 210. The drain of the access transistor 210 is the drain of the HEMT 100. The gate of the core transistor 204 is the gate layer 112 of the HEMT 100 and is electrically coupled to a gate voltage (V_{G}). The gate of the first field plate transistor 206 is the first field plate 118 of the HEMT 100 and is electrically coupled to the first field plate voltage (V_{FP1}). The gate of the second field plate transistor 208 is the second field plate 120 of the HEMT 100 and is electrically coupled to the second field plate voltage (V_{FP2}). A source voltage (V_{S}) is electrically coupled to the source of the HEMT 100, and a drain voltage (V_{D}) is electrically coupled to the drain of the HEMT 100.

Also, the intrinsic source voltage of the core transistor 204 is represented by Vₛᵢ, and the intrinsic drain voltage of core transistor 204 is represented by V_{di}, which is also the intrinsic source voltage of first field plate transistor 206. The intrinsic source voltage of the access transistor 210 is represented by Vₛₚᵢ, which also represents the intrinsic drain voltage of the second field plate transistor 208. The intrinsic source voltage of the second field plate transistor 208, which can also be the intrinsic drain voltage of the first field plate transistor 206, is represented by V_{gpi}.

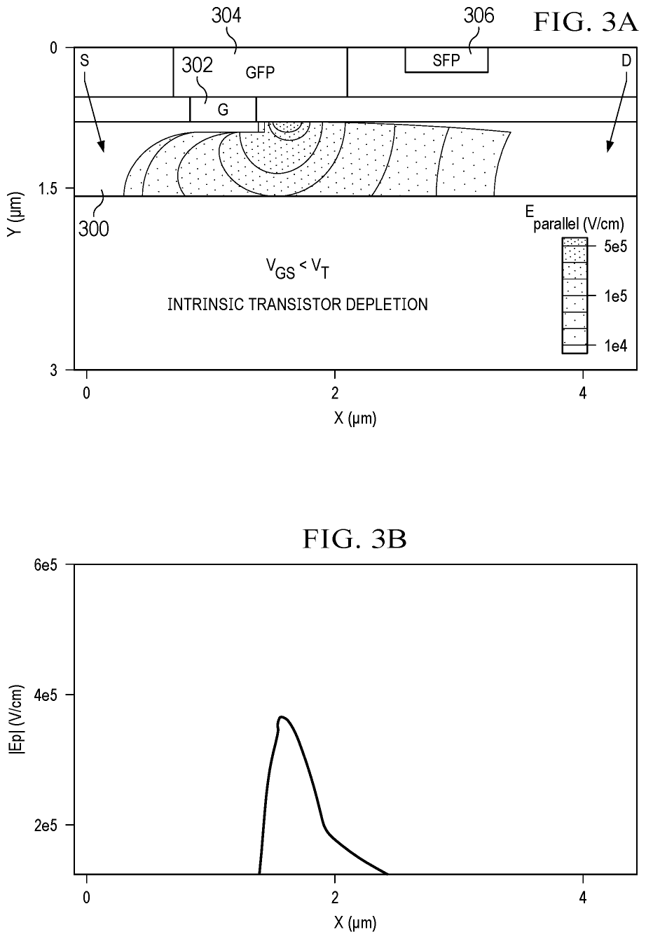

FIGS. 3A, 4A, and 5A each illustrate an example HEMT with a distribution of an electric field in a substrate 300 under different circumstances. The HEMT includes a gate G 302 on the substrate 300, a gate-coupled field plate (GFP) 304, and a source-coupled field plate (SFP) 306. A source S and a drain D in the substrate 300 are also indicated. FIGS. 3B, 4B, and 5B illustrate peaks of respective electric fields in the substrate 300 under the circumstances of FIGS. 3A, 4A, and 5A. In these figures, the GFP 304 is interchangeably referred to as a first field plate (FP1), and the SFP 306 is interchangeably referred to a second field plate (FP2). GFP 304 can be represented by the first field plate transistor 206 of FIG. 2, and SFP 306 can be represented by the second field plate transistor 208 of FIG. 2.

In FIG. 3A, a gate-to-source voltage (V_{GS}) is less than the threshold voltage (V_{T}) of the core transistor. The source voltage (V_{S}) may be zero volts, and the gate voltage (V_{G}) may be zero volts or another voltage such that the gate-to-source voltage (V_{GS}) is less than the threshold voltage (V_{T}). A drain voltage (V_{D}) begins to ramp up.

Initially, the gate voltage (V_{G}) is below the threshold voltage (V_{T}) of the core transistor. The field plate transistors are turned on. The disabled core transistor can sustain an electric field (E-field), which peaks in the substrate 300 at the edge of the gate G 302 and decreases across the GFP transistor, as shown in FIGS. 3A and 3B.

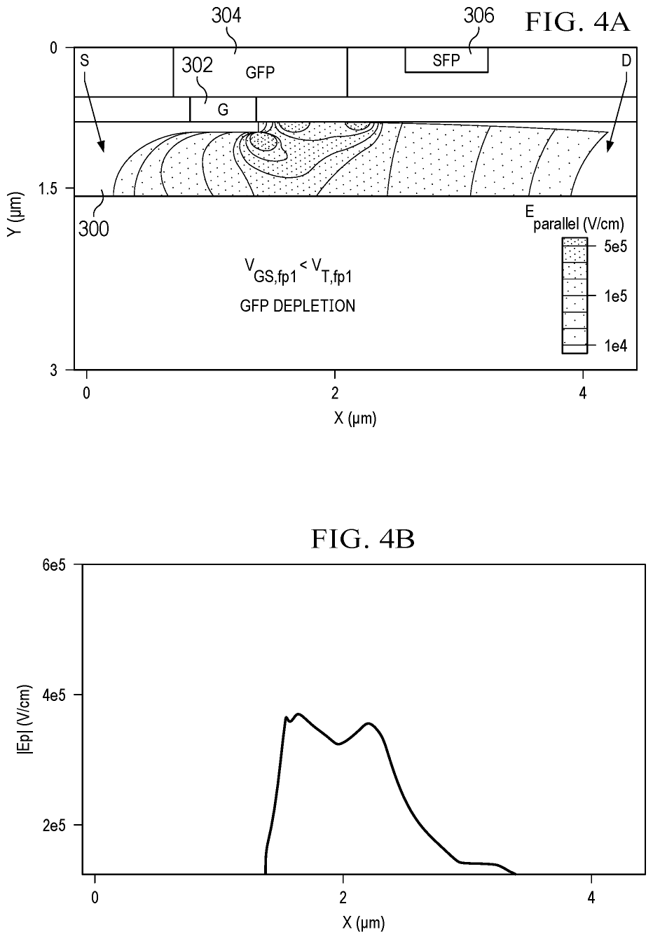

As the drain voltage (V_{D}) further increases, a difference between the first field plate voltage (V_{FP1}) (of the GFP 304) and intrinsic drain-voltage (V_{di}) of the core transistor (or intrinsic source voltage of GFP transistor) is less than the threshold voltage of the GFP transistor (V_{to,FP1}) (e.g., V_{FP1}−V_{di}<V_{to,FP1}), and the GFP transistor is turned off/depleted. Another E-field can be sustained across the GFP transistor. The E-field can peak at the edge of the GFP 304 and decreases across the SFP transistor which remains turned on, as shown in FIGS. 4A and 4B.

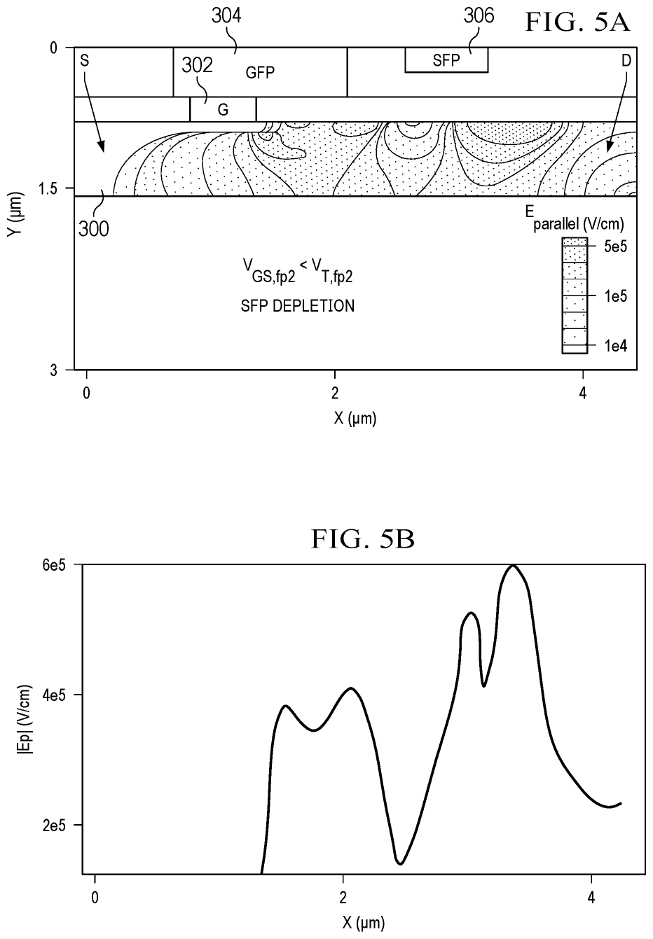

As the drain voltage (V_{D}) further increases, a difference between the second field plate voltage (V_{FP2}) (of the SFP 306) and intrinsic drain-voltage (V_{gpi}) of the GFP transistor (or intrinsic source voltage of SFP transistor) is less than the threshold voltage of the SFP transistor (V_{to,FP2}) (e.g., V_{FP2}−V_{gpi}<V_{to,FP2}), the SFP transistor is turned off/depleted, and yet another E-field can be sustained across the depleted SFP transistor. The E-field can peak at the edge of the SFP 306, as shown in FIGS. 5A and 5B.

The additional E-fields mean the depleted GFP and SFP transistors can take up additional voltage drops between the source and the drain and can reduce the peak E-field of the core transistor, which can increase the overall break down voltage of the HEMT transistor.

The threshold voltages of the GFP and SFP transistors (V_{to,FP1} and V_{to,FP2}, respectively) can be based on the height of the field plates (e.g., GFP 304 and SFP 306) over a barrier layer of the substrate 300. The threshold voltages (V_{to,FP1} and V_{to,FP2}, respectively) can be configured to move the E-field distribution and to improve the break down voltage and reliability.

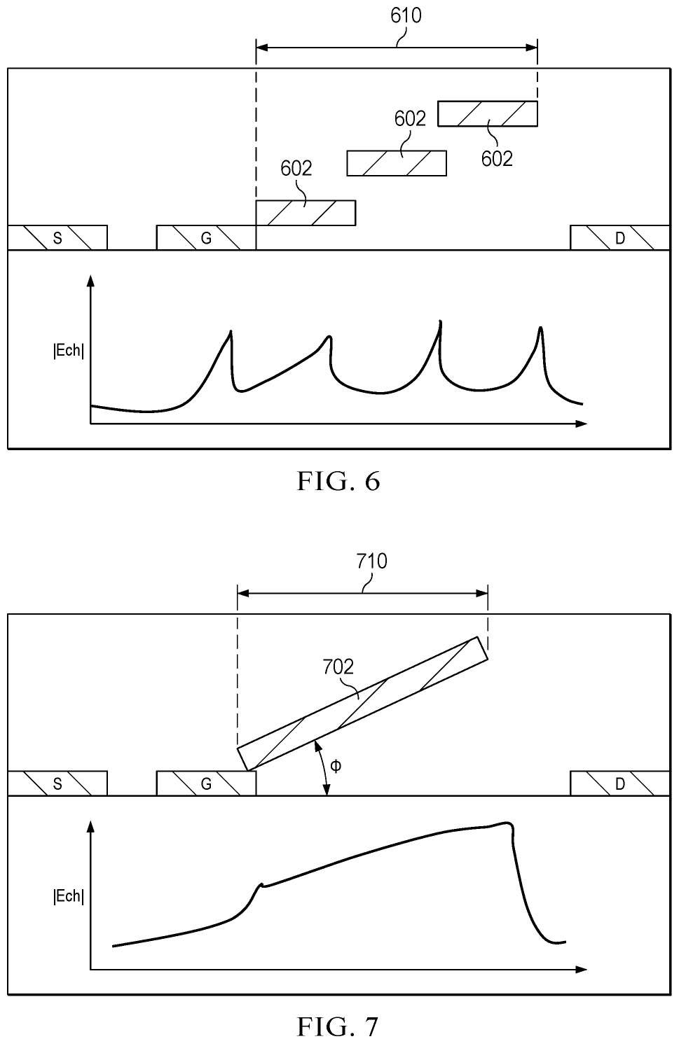

The BV can be increased by increasing the voltage sustained across a field plate, which can reduce the drain-to-source voltage (V_{DS}) across the core transistor. One way is by having multiple leveled field plates 602, as shown in FIG. 6, with each field plate 602 having a different height over the barrier layer of the HEMT transistor. Each field plate 602 provides a field plate transistor having a different threshold voltage. FIG. 6 shows the magnitude of the electric field (|Ech|) from a gate G to a drain D, where the area under the electric field curve is equal to the drain-to-source voltage (V_{DS}). With multiple leveled field plates 602, multiple E-field peaks occur at the discontinuities between adjacent field plates 602. The E-field drops quickly after each peak, resulting in small area under the E-field curve. A smaller area leads to inefficient drain-to-source voltage (V_{DS}) blocking and reduced BV. The first E-field peak at the edge of the gate G is high, which degrades the gate TDDB.

A single-sided slanted gate field plate 702 as shown in FIG. 7, which extends from one side of the gate G towards the drain D and has a slope (with a slope angle ϕ) with respect to the top surface of the semiconductor substrate (e.g., the barrier layer), can increase the BV. The slanted gate field plate 702 can also represent multiple field plates having multiple heights over the barrier layer, with each field plate providing a field plate transistor having a different threshold voltage. With a single-sided slanted gate field plate, no gap is between field plates and the number of peaks is reduced. This increases the area under the E-field curve, which represents more efficient drain-to-source voltage (V_{DS}) blocking and increases the BV. A lateral dimension 710 of the slanted gate field plate 702 can be reduced compared with a total lateral dimension 610 of the multiple leveled field plates 602 in FIG. 6 for the same drain-to-source voltage (V_{DS}) blocking. A distance between the gate and drain may be reduced, which may increase gate-drain capacitance (Miller capacitance) and gate-drain leakage current. Slope considerations may be conflicting. A small slope (e.g., small slope angle ϕ) may reduce peak E-field and improve TDDB; however, a small slope (e.g., small slope angle ϕ) may also reduce an area under the E-field slope and the area under the E-field curve, which may reduce BV for a same peak magnitude of E-field and may reduce drain-to-source voltage (V_{DS}) blocking. Conversely, a small slope may, for a same drain-to-source voltage (V_{DS}) as a high slope, may yield a higher peak magnitude of E-field.

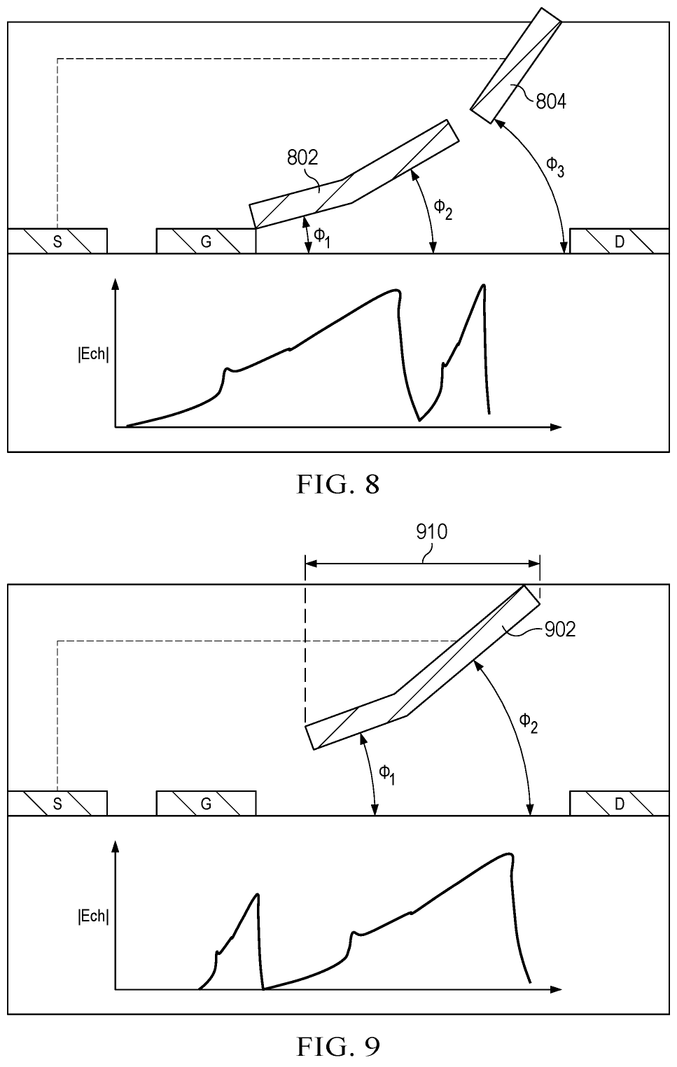

A single-sided slanted gate field plate 802 with multiple slopes (with respective slope angles ϕ₁, ϕ₂) can be combined with a single-sided slanted source field plate 804 with a slope (with a slope angle ϕ₃), as shown in FIG. 8. The first slope (with the slope angle ϕ₁) of the slanted gate field plate 802 can be made small to reduce peak E-field at the gate and improve gate TDDB, and the second slope (with the slope angle ϕ₂) of the slanted gate field plate 802 and the third slope (with the slope angle ϕ₃) of the slanted source field plate 804 can be made large to increase the E-field curve slopes (and E-field curve area) and increase BV. The slanted source field plate 804 can screen the gate G from the drain D and reduces gate-drain capacitance and leakage current. The slanted source field plate 804 can be used for power routing to the source S. An E-field peak may occur at the gap between the gate field plate 802 and the source field plate 804. The gate field plate 802 and the source field plate 804 can be separated by a dielectric to avoid an electrical short or jump between the gate field plate 802 and the source field plate 804.

A single-sided slanted source field plate 902 alone with multiple slopes (with respective slope angles ϕ₁, ϕ₂) can also improve E-field distribution, as shown in FIG. 9. The first slope (with the slope angle ϕ₁) can be made small and extend closer to the gate G to reduce a peak E-field and improve gate TDDB, and the second slope (with the slope angle ϕ₂) can be made large to increase the E-field curve slopes (and E-field curve area) and increase BV. The dependence of TDDB on process, voltage, and temperature (PVT) may be reduced. A large second slope (with the slope angle ϕ₂) can reduce the overall lateral dimension 910 of the slanted source field plate 902 and reduce source-drain capacitance. The slanted source field plate 902 can screen the gate G from the drain D and reduces gate-drain capacitance and leakage current. The slanted source field plate 902 can be used for power routing to the source S. The slanted source field plate 902 may have reduced effectiveness in improving TDDB because metal discontinuity may remain.

Although various aspects of FIGS. 7 through 9 have been described individually or in combination with other aspects, any aspect of FIGS. 7 through 9 may be combined with any other aspect of FIGS. 7 through 9. Examples described subsequently may include differing aspects of FIGS. 7 through 9, and other examples may include additional or different aspects of FIGS. 7 through 9. More generally, any aspect of an example described herein may be combined with any other aspect of another example described herein.

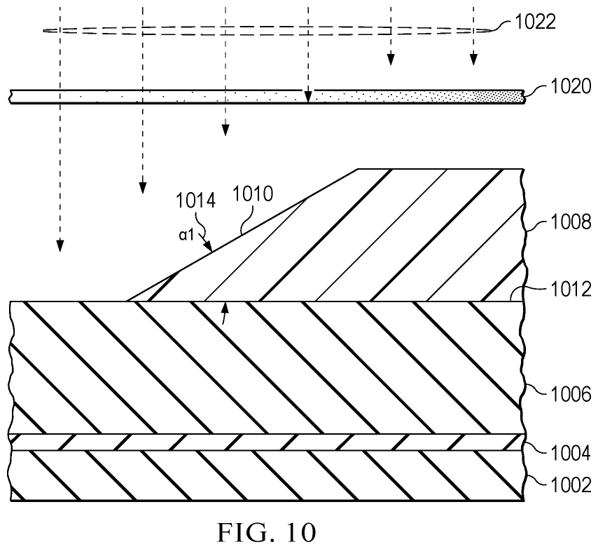

FIGS. 10, 11, and 12 illustrate aspects of grayscale photolithography and an etch process implemented in some examples for forming a slanted field plate. FIG. 10 shows a first dielectric layer 1002, an etch stop layer 1004 over the first dielectric layer 1002, and a second dielectric layer 1006 over the etch stop layer 1004. A patterned photoresist 1008 is over the second dielectric layer 1006 and is patterned to have a slanted surface 1010 relative to a top surface 1012 of the second dielectric layer 1006 on which the patterned photoresist 1008 is disposed. The slanted surface 1010 forms a first angle (al) 1014 with the plane of the top surface 1012.

To form the patterned photoresist 1008, a photoresist layer is formed (e.g., deposited by spin-on) and is patterned into the patterned photoresist 1008 using grayscale photolithography. In the grayscale photolithography according to some examples, a mask 1020 is implemented that allows light 1022 (e.g., ultraviolet (UV) light or other electromagnetic radiation) to be blocked or pass therethrough. The intensity of the light 1022 that passes through the mask 1020 varies (e.g., in grayscale) across the photoresist layer to achieve the slanted surface 1010 in the patterned photoresist 1008. Examples of variation in intensity of light that may be achieved using different masks are described in more detail subsequently.

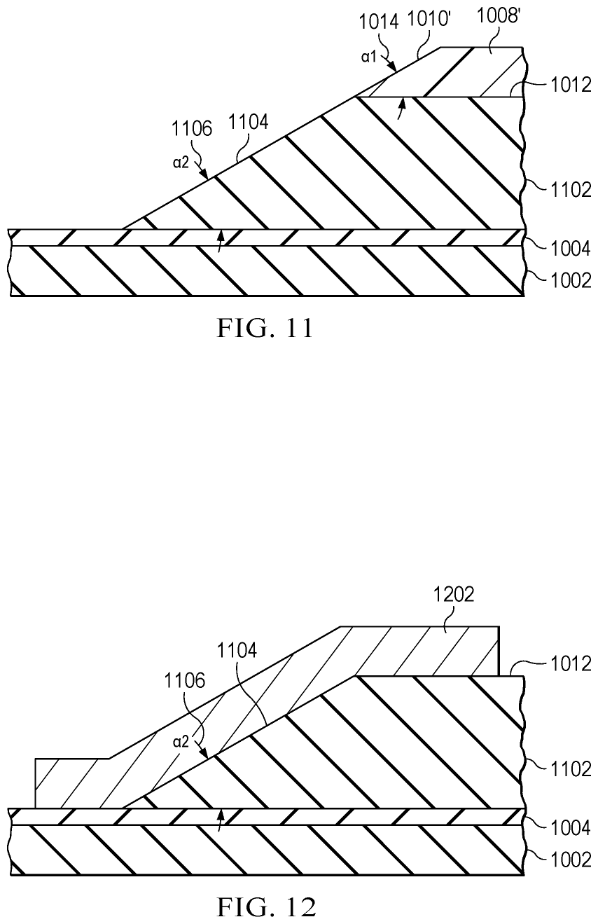

In FIG. 11, an anisotropic etch process is implemented to form a slanted surface 1104 in a dielectric structure 1102 formed from the second dielectric layer 1006. The anisotropic etch may be, for example, a reactive ion etch (RIE). The etch process simultaneously consumes the patterned photoresist 1008 and the second dielectric layer 1006 such that the slanted surface 1104 is formed in the dielectric structure 1102. The consumption of the patterned photoresist 1008 may result in the remaining patterned photoresist 1008′ and remaining slanted surface 1010′ following the etch process, which may subsequently be removed, e.g., by an ash process. The etch process generally does not consume the etch stop layer 1004 or consumes the etch stop layer 1004 at a significantly lower rate than the second dielectric layer 1006 such that the etch is stopped at the etch stop layer 1004.

The slanted surface 1104 forms a second angle (α2) 1106 with a plane parallel with the plane of the top surface 1012 (e.g., a plane of a bottom surface of the dielectric structure 1102). In some examples, the second angle (α2) 1106 is less than 900 and is greater than 0°. More particularly, the second angle (α2) 1106 may be equal to or greater than 6°, 9°, 12°, 15°, 18°, etc., and may be equal to or less than 60°, 50°, 35°, 30°, etc. Any slope angle in various examples described herein may be a same or similar angle. The second angle (α2) 1106 may be less than, equal to, or greater than the first angle (α1) 1014. For example, if the etch process consumes the patterned photoresist 1008 at a greater or faster rate than the rate at which the second dielectric layer 1006 is consumed, the second angle (α2) 1106 may be less than the first angle (α1) 1014. If the etch process consumes the patterned photoresist 1008 at a rate equal to the rate at which the second dielectric layer 1006 is consumed, the second angle (α2) 1106 may be equal to the first angle (α1) 1014. If the etch process consumes the patterned photoresist 1008 at a lesser or slower rate than the rate at which the second dielectric layer 1006 is consumed, the second angle (α2) 1106 may be greater than the first angle (α1) 1014. A difference between the respective rates at which the patterned photoresist 1008 and second dielectric layer 1006 are consumed by the etch process can be configured to result in a slanted surface in the dielectric structure 1102. Hence, the chemistry of the etch process may be tuned to achieve a slanted surface 1104 of the dielectric structure 1102.

In FIG. 12, a field plate 1202 is formed on the slanted surface 1104 of the dielectric structure 1102. As described in detail subsequently, the field plate 1202 may be formed by depositing one or more metals on the exposed portion of the etch stop layer 1004 and on the slanted surface 1104 and remaining top surface 1012 of the dielectric structure 1102. The metal(s) may then be patterned using a photolithography process (e.g., binary photolithography) and an etch process.

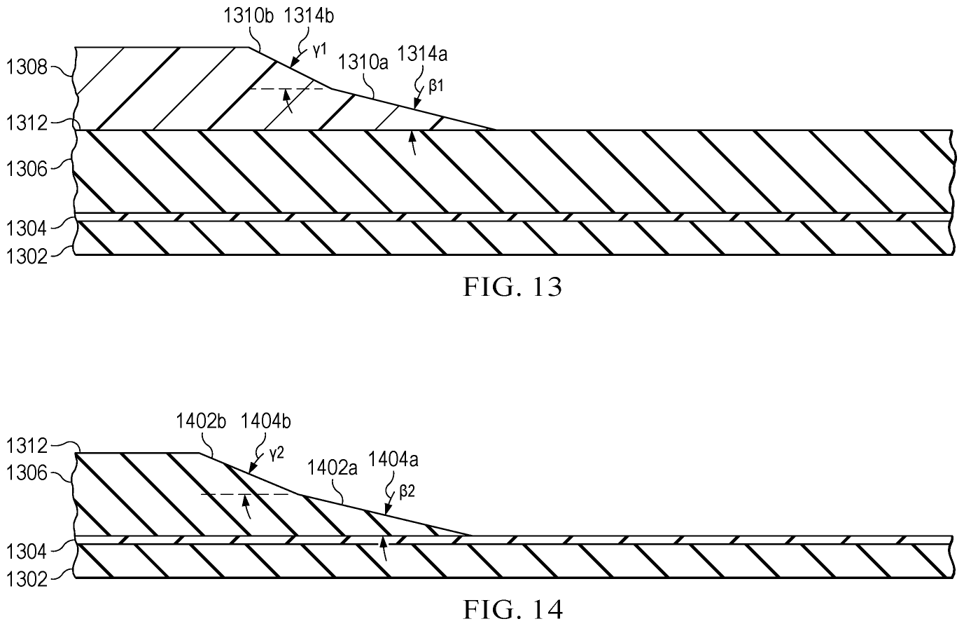

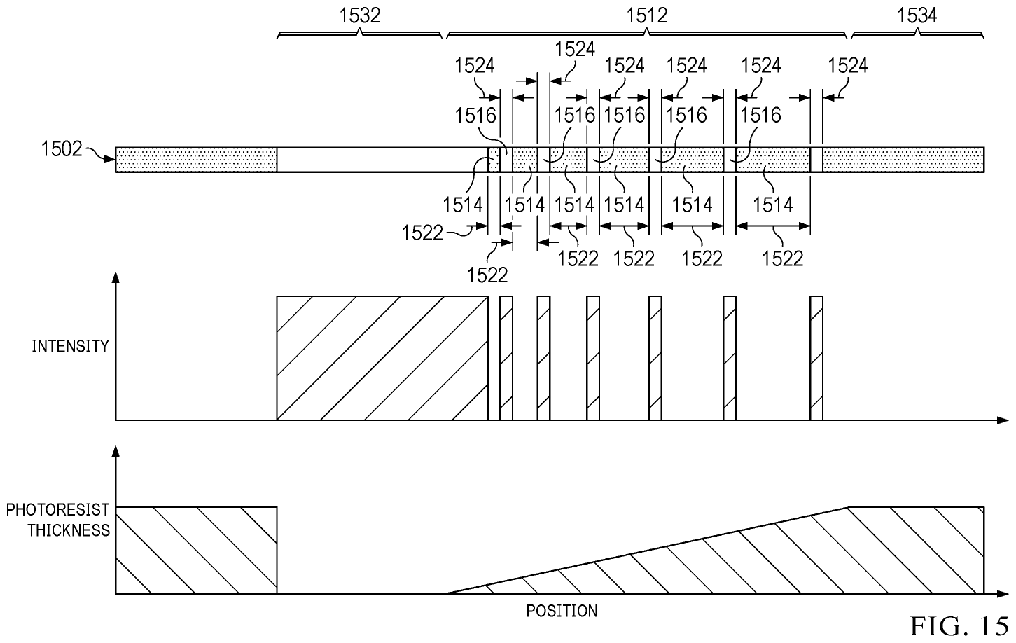

FIGS. 13 and 14 illustrate additional aspects of grayscale photolithography and an etch process implemented in some examples. As shown in FIGS. 13 and 14, multiple slopes may be generated in a dielectric structure. The multiple slopes may be generated using one mask or multiple masks.

FIG. 13 shows a first dielectric layer 1302, an etch stop layer 1304 over the first dielectric layer 1302, and a second dielectric layer 1306 over the etch stop layer 1304. A photoresist 1308 is over the second dielectric layer 1306 and is patterned to have a multi-sloped slanted surface relative to a top surface 1312 of the second dielectric layer 1306 on which the photoresist 1308 is disposed. The multi-sloped slanted surface includes a first slanted surface portion 1310a and a second slanted surface portion 1310b. The first slanted surface portion 1310a extends from the top surface 1312 of the second dielectric layer 1306 to the second slanted surface portion 1310b, and the second slanted surface portion 1310b extends from the first slanted surface portion 1310a to the top surface of the photoresist 1308.

The first slanted surface portion 1310a forms a first angle (β1) 1314a with the plane of the top surface 1312, and the second slanted surface portion 1310b forms a second angle (γ1) 1314b with a plane parallel to the plane of the top surface 1312. The first angle (β1) 1314a and the second angle (γ1) 1314b are unequal angles. In some examples, the first angle (β1) 1314a is greater than the second angle (γ1) 1314b (e.g., β1>γ1). In some examples, the first angle (β1) 1314a is less than the second angle (γ1) 1314b (e.g., β1<γ1). The photoresist 1308 is patterned using grayscale photolithography, as described above with respect to FIG. 10. The mask used to pattern the photoresist 1308 implements a compound intensity function of light to be incident on the photoresist 1308 to achieve the multi-sloped slanted surface.

In FIG. 14, an anisotropic etch process is implemented to form a multi-sloped slanted surface in a dielectric structure 1401 formed from the second dielectric layer 1306. The anisotropic etch process may be as described above with respect to FIG. 11. The multi-sloped slanted surface of the dielectric structure 1401 includes a first slanted surface portion 1402a and a second slanted surface portion 1402b. The first slanted surface portion 1402a extends from the top surface of the etch stop layer 1304 to the second slanted surface portion 1402b, and the second slanted surface portion 1402b extends from the first slanted surface portion 1402a to the remaining top surface 1312 of the dielectric structure 1401.

The first slanted surface portion 1402a forms a third angle (β2) 1404a with a plane parallel with the plane of the top surface 1312 (e.g., a plane of a bottom surface of the dielectric structure 1401). The second slanted surface portion 1402b forms a fourth angle (γ2) 1404b with a plane parallel with the plane of the top surface 1312 (e.g., a plane of a bottom surface of the dielectric structure 1401). The third angle (β2) 1404a and the fourth angle (γ2) 1404b may be less than, equal to, or greater than the first angle (β1) 1314a and the second angle (γ1) 1314b, respectively, like described above with respect to FIG. 11. In some examples, the third angle (β2) 1404a and the fourth angle (γ2) 1404b are less than the first angle (β1) 1314a and the second angle (γ1) 1314b, respectively (e.g., β2<β1, γ2<γ1). In some examples, the third angle (β2) 1404a and the fourth angle (γ2) 1404b are equal to the first angle (β1) 1314a and the second angle (γ1) 1314b, respectively (e.g., β2=β1, γ2=γ1). In some examples, the third angle (β2) 1404a and the fourth angle (γ2) 1404b are greater than the first angle (β1) 1314a and the second angle (γ1) 1314b, respectively (e.g., β2>β1, γ2>γ1).

Although respective transitions from the first slanted surface portion 1310a to the second slanted surface portion 1310b or from the first slanted surface portion 1402a to the second slanted surface portion 1402b are shown by a sharp angle, another surface may be between the respective slanted surface portions. For example, a gradual change in slope may be in a transition surface portion to transition from the slope of the first slanted surface portion to the slop of the second slanted surface portion. A transition surface may be a flat surface, a curved surface, a convex surface, a concave surface, any polynomial surface, etc. The grayscale photolithography may be tuned to implement such a transition surface.

In some examples, multiple masks may be implemented to achieve multiple slopes, where each slope of the multiple slopes is in a respective dielectric structure formed from a dielectric layer. An etch stop layer may be between vertically neighboring dielectric layers. Each mask may be used the pattern a photoresist having a slanted surface, which is transferred into a respective dielectric layer to form the corresponding dielectric structure.

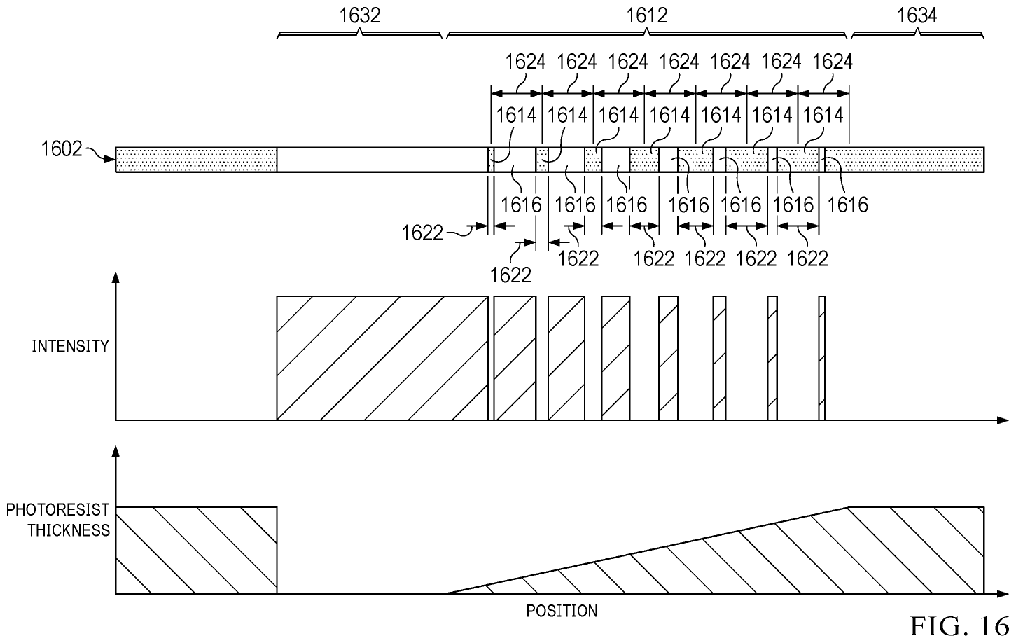

FIGS. 15 and 16 illustrate aspects of masks that may be implemented in grayscale photolithography. FIGS. 15 and 16 show cross-sections of respective masks 1502, 1602 and corresponding intensity profiles and photoresist thickness profiles. The masks 1502, 1602 have respective grayscale regions 1512, 1612. The grayscale regions 1512, 1612 produce equal photoresist thickness profiles. The grayscale regions 1512, 1612 have respective fill factor distributions that achieve the corresponding intensity profiles and photoresist thickness profiles.

In the grayscale region 1512 of FIG. 15, the mask 1502 includes opaque patterns 1514 and transparent patterns 1516. The opaque patterns 1514 have respective dimensions 1522 that vary through the grayscale region 1512 (e.g., that increase from a full exposure region 1532 to a full blocking region 1534). The transparent patterns 1516 have respective dimensions 1524 that are equal to each other through the grayscale region 1512. Each dimension 1524 may be below the resolution limit. The pitches between neighboring opaque patterns 1514 (e.g., center-to-center pitch) vary through the grayscale region 1512 (e.g., that increase from a full exposure region 1632 to a full blocking region 1634). The varying dimensions 1522 of the opaque patterns 1514 and the constant dimensions 1524 of the transparent patterns 1516 result in a fill factor distribution in the grayscale region 1512 of the mask 1502.

In the grayscale region 1612 of FIG. 16, the mask 1602 includes opaque patterns 1614 and transparent patterns 1616. The opaque patterns 1614 have respective dimensions 1622 that vary through the grayscale region 1612 (e.g., that increase from a full exposure region 1632 to a full blocking region 1634). The pitches 1624 between neighboring opaque patterns 1614 (e.g., center-to-center pitch) are equal through the grayscale region 1612. The transparent patterns 1616 have respective dimensions that correspondingly vary through the grayscale region 1612 (e.g., that decrease from a full exposure region 1632 to a full blocking region 1634). Each dimension of the transparent patterns 1616 may be below the resolution limit. The varying dimensions 1622 of the opaque patterns 1614 and the constant pitches 1624 result in a fill factor distribution in the grayscale region 1612 of the mask 1602.

The intensity from light exposure through the masks 1502, 1602 in the grayscale regions 1512, 1612 accumulates locally to achieve the slope in the respective photoresist profile. The accumulation may be expressed mathematically by a convolution function. Hence, the accumulation of intensity may be greater in the respective grayscale region 1512, 1612 near a respective full exposure region 1532, 1632 and linearly decrease to a respective full blocking region 1534, 1634. The accumulated intensity may result in the slope of the photoresist. The local accumulation or effective intensity correlates with the resulting thickness of the photoresist. No image (e.g., discrete or binary image) is created in the photoresist in the grayscale region 1512, 1612. In the illustrated examples, the fill factor distributions of the grayscale regions 1512, 1612 result in a linear accumulation of intensity, which results in a slanted surface in the photoresist with a uniform slope throughout the slanted surface.

With respect to FIG. 15, as a constant dimension 1524 is used, calculating the local accumulated intensity may be more difficult. Small local changes may be modified by shifting a transparent pattern laterally. Any change affects neighboring areas on the photoresist. If a transparent pattern is shifted to increase the intensity at one local area of the photoresist, the intensity may be decreased at a neighboring local area. Additional space can be added to the neighboring local area but may lead to over-compensation.

With respect to FIG. 16, as a constant pitch is used, the fill of transparent and opaque patterns (e.g., a fill factor) may be adjusted to modulate the photoresist thickness. An almost linear correlation may be present between fill factor and photoresist thickness. A transfer function may be easily defined. Small local changes may be modified by changing the fill factor of one single element without affecting a neighboring element. Complexity in designing and generating a photomask for a slanted field plate having multiple slopes may be reduced using constant pitch.

The above examples for grayscale photolithography have been illustrated and described with respect to positive tone photoresists. In other examples, grayscale photolithography may implement a negative tone photoresist. Further, although described in the context of grayscale photolithography using masks, grayscale photolithography may be implemented using a maskless grayscale photolithography technique or a digital grayscale photolithography technique. Additionally, the grayscale photolithography described above may be for a one-dimensional (1D) grayscale pattern (e.g., a linear 1D pattern), and in other examples, grayscale photolithography may implement a two-dimensional (2D) grayscale pattern (e.g., linear 2D patterns) to modulate a field plate along a length of a channel and with the termination of the FP near a width-edge of an active area (e.g., a finger active area) in which the channel is disposed.

Further, the slanted surfaces or slanted surface portions described above have a uniform slope throughout the respective slanted surface or slanted surface portion. Each slanted surface or slanted surface portion is a plane throughout the respective slanted surface or slanted surface portion. In other examples, grayscale photolithography may be implemented to achieve different types of surfaces. For example, grayscale photolithography may be used to form a concave surface, a convex surface, the like, or another slanted surface.

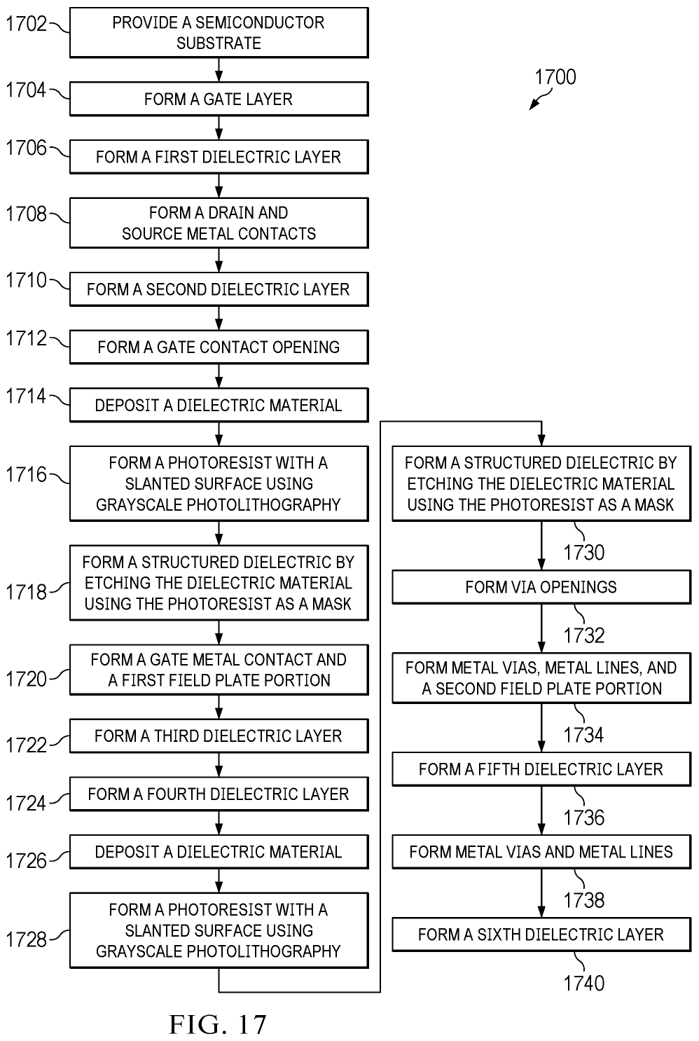

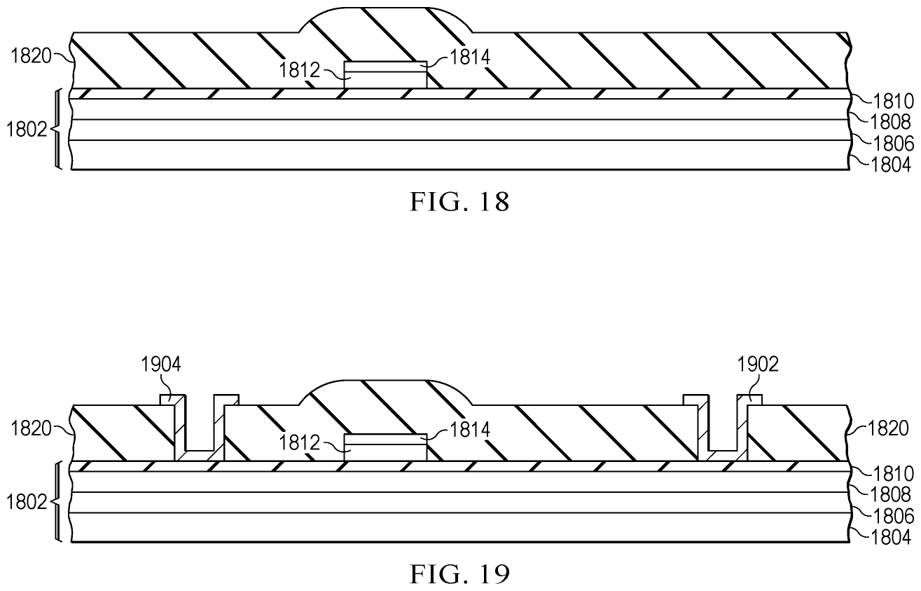

FIG. 17 is a flowchart of a method 1700 of manufacturing a semiconductor device (e.g., a HEMT) according to some examples. The method 1700 of FIG. 17 is illustrated by and described in the context of FIGS. 18 through 29, which illustrate cross-sectional views of the semiconductor device at various stages of manufacturing.

Referring to block 1702 of FIG. 17 and to FIG. 18, a semiconductor substrate 1802 is provided. As illustrated, providing the semiconductor substrate 1802 may include providing a support substrate 1804, forming one or more transition layers 1806 over and on the support substrate 1804, forming a channel layer 1808 over and on the transition layer(s) 1806, and forming a barrier layer 1810 over and on the channel layer 1808. The support substrate 1804 may be a bulk semiconductor or isolation substrate, a semiconductor-on-insulator (SOI) substrate, or any other appropriate substrate. For example, the support substrate 1804 may be or include a bulk silicon, silicon oxide, silicon carbide wafer, sapphire wafer, a QROMIS substrate technology (QST®) substrate, etc. The transition layer(s) 1806 may include any number of layers of any materials that are configured to accommodate lattice mismatch between the support substrate 1804 and the channel layer 1808 (e.g., to reduce or minimize lattice defect generation and/or propagation in the channel layer 1808). For example, the transition layer(s) 1806 may have a gradient concentration of one or more elements in a direction normal to the upper surface of the support substrate 1804. Further, a layer of the transition layer(s) 1806 may be a doped buffer layer. The transition layer(s) 1806 may be formed on the support substrate 1804 by epitaxially growing the transition layer(s) 1806 using, for example, metal-organic chemical vapor deposition (MOCVD), molecular beam epitaxy (MBE), low pressure chemical vapor deposition (LPCVD), or another epitaxy process.

The channel layer 1808 is configured, possibly in conjunction with the barrier layer 1810, to conduct and confine charge carriers (such as electrons) within two dimensions. In some examples, the channel layer 1808 is configured to include a two-dimensional electron gas (2DEG). The 2DEG may be formed by energy band bending resulting from the barrier layer 1810 being over and on the channel layer 1808. In some examples, the channel layer 1808 may be a portion of the support substrate 1804 (e.g., without the transition layer(s) 1806). In some examples, the channel layer 1808 includes a gallium nitride (GaN) layer and, in such examples, may be referred to as a GaN channel layer. In some examples, the channel layer 1808 may be or include indium aluminum gallium nitride (InᵢAlⱼGa₁₋ᵢ₋ⱼN) (where 0≤i≤1, 0≤j≤1, and 0≤i+j≤1). In some examples, the material of the channel layer 1808 is or includes an unintentionally doped material, such as a material doped by diffusion of dopants from another layer, or is or includes an intrinsic material. Other materials may be implemented for the channel layer 1808. The channel layer 1808 may be formed on the uppermost transition layer 1806 by epitaxially growing the channel layer 1808 using MOCVD, MBE, LPCVD, or another epitaxy process.

The barrier layer 1810, in some examples, may be or include an aluminum gallium nitride (AlGaN) layer and, in such examples, may be referred to as an AlGaN barrier layer. In some examples, the barrier layer 1810 may be or include indium aluminum gallium nitride (InₖAlₗGa₁₋ₖ₋ₗN) (where 0≤k≤1, 0≤1≤1, and 0≤k+l≤1). Other materials may be implemented for the barrier layer 1810. The barrier layer 1810 may be formed on the channel layer 1808 by epitaxially growing the barrier layer 1810 using MOCVD, MBE, LPCVD, or another epitaxy process.

At block 1704, a gate layer 1812 is formed over and on the barrier layer 1810. In some examples, the gate layer 1812 is or includes a semiconductor layer of a semiconductor material. Further, in some examples, the gate layer 1812 is doped with a dopant. In some examples, the gate layer 1812 is doped with a p-type dopant. In some examples, the gate layer 1812 may be or include a gallium nitride (GaN) layer, or more generally, indium aluminum gallium nitride (InₘAlₙGa₁₋ₘ₋ₙN) (where 0≤m≤1, 0≤n≤1, and 0≤m+n≤1), and the dopant with which the gate layer 1812 is doped is a p-type dopant, which may be or include magnesium (Mg), carbon (C), zinc (Zn), the like, or a combination thereof. In examples in which the gate layer 1812 is gallium nitride (GaN) doped with a p-type dopant, the gate layer 1812 may be referred to as a p-doped GaN (pGaN) layer. Further, in examples in which the gate layer 1812 is gallium nitride (GaN) doped with a magnesium, the gate layer 1812 may be referred to as a magnesium doped gallium nitride (GaN:Mg) layer. In some examples, a concentration of the dopant in the gate layer 1812, which is electrically activated, is equal to or greater than 1×10¹⁷ cm⁻³. In some examples, the concentration is equal to or greater than 1×10¹⁸ cm⁻³. In some examples, the dopant in the gate layer 1812 may have a uniform concentration. In some examples, the dopant in the gate layer 1812 may have a gradient concentration. Other materials, dopants, and/or concentrations may be implemented in other examples.

The gate layer 1812 may be formed by depositing a material of the gate layer 1812 and patterning the material into the gate layer 1812. In some examples, the material of the gate layer 1812 may be deposited by epitaxial growth, such as by MOCVD, MBE, LPCVD, plasma enhanced chemical vapor deposition (PECVD), atomic layer epitaxy, or another epitaxy process. The material into the gate layer 1812 may be doped in situ during deposition (e.g., epitaxial growth) or by implantation (e.g., ion implantation) subsequent to deposition. The material of the gate layer 1812 may be patterned into the gate layer 1812 using appropriate photolithography and etch processes. For example, a photoresist is deposited (e.g., by spin-on) over the material of the gate layer 1812 and patterned using photolithography. With the patterned photoresist, an etch process, such as an anisotropic etch like an RIE or the like, is performed, using the patterned photoresist as a mask, to pattern the gate layer 1812. After the etch process, the photoresist is removed, such as by ashing.

The illustrated example in FIG. 18 also includes a silicon layer 1814 formed over and on the gate layer 1812. In other examples, the silicon layer 1814 may be omitted. The silicon layer 1814, in some examples, is or includes polysilicon. Further, in some examples, the silicon layer 1814 is doped with a dopant, such as with a p-type dopant. The dopant with which the silicon layer 1814 is doped may be a same conductivity type (e.g., p-type) as the dopant with which the gate layer 1812 is doped. An example p-type dopant of the silicon layer 1814 includes boron (B) or the like. In some examples, a concentration of the dopant (e.g., p-type dopant) in the silicon layer 1814 may be equal to or greater than 1×10¹⁹ cm⁻³, and more particularly, equal to or greater than 1×10²¹ cm⁻³ (e.g., 2×10²¹ cm⁻³). In some examples, a concentration of the dopant in the silicon layer 1814 may be less than 5×10²¹ cm⁻³. In some examples, a concentration of the dopant (e.g., p-type dopant, such as boron (B)) in the silicon layer 1814 is at least two (2) times greater than (such as from two (2) to ten (10) or one hundred (100) times greater than) a concentration of the dopant (e.g., p-type dopant, such as magnesium (Mg), carbon (C), or zinc (Zn)) in the gate layer 1812. The silicon layer 1814, in some examples, forms a Schottky junction with the gate layer 1812 at the interface of the gate layer 1812 and the silicon layer 1814. In other examples, another conductive layer may be in the place of or included with (e.g., over and on) the silicon layer 1814. Such other conductive layer may be or include a refractory metal (e.g., chromium, molybdenum, tantalum, tungsten, titanium, hafnium, or iridium), a conductive ceramic (e.g., indium tin oxide (ITO), or any other front-end-of-the-line (FEOL) compatible conductive material. Incorporating a silicon layer on a gate layer may achieve improved gate depletion during operation of the semiconductor device, decoupling of a parasitic capacitance, and retention of a high energy barrier height Schottky junction.

To form the silicon layer 1814, the silicon material (e.g., polysilicon) of the silicon layer 1814 may be deposited after the material of the gate layer 1812 is deposited, and the silicon may be patterned into the silicon layer 1814 with the patterning of the gate layer 1812. In some examples, the silicon may be deposited by chemical vapor deposition (CVD), such as PECVD, or another deposition process. The silicon material of the silicon layer 1814 may be doped in situ during deposition or by implantation (e.g., ion implantation) subsequent to deposition. Other processing to form the silicon layer 1814 may be implemented.

At block 1706, a first dielectric layer 1820 is formed over the semiconductor substrate 1802 (e.g., the barrier layer 1810) and the gate layer 1812. If included, the first dielectric layer 1820 is also formed over the silicon layer 1814. The first dielectric layer 1820 may be a pre-metal dielectric layer (PMD). In some examples, the first dielectric layer 1820 is or includes silicon nitride (SiN); although in other examples, the first dielectric layer 1820 may be or include another one or more other dielectric materials. The first dielectric layer 1820 may be deposited using any appropriate deposition process, such as CVD, LPCVD, PECVD, or the like.

Referring to block 1708 of FIG. 17 and to FIG. 19, a drain metal contact 1902 and a source metal contact 1904 are formed through the first dielectric layer 1820. The drain metal contact 1902 and the source metal contact 1904 may be in a MET0 metal layer. The drain metal contact 1902, as illustrated, is conformally in a source/drain contact opening and contacts the barrier layer 1810 to electrically couple a drain in the channel layer 1808. Similarly, the source metal contact 1904, as illustrated, is conformally in a source/drain contact opening and contacts the barrier layer 1810 to electrically couple a source in the channel layer 1808. In other examples, the drain metal contact 1902 and the source metal contact 1904 may extend into the barrier layer 1810, through the barrier layer 1810 to and/or into the channel layer 1808, or through the barrier layer 1810 and channel layer 1808 to and/or into the transition layer(s) 1806.

Respective source/drain contact openings may be formed through the first dielectric layer 1820 to and/or into the barrier layer 1810, through the barrier layer 1810 to and/or into the channel layer 1808, or through the barrier layer 1810 and channel layer 1808 to and/or into the transition layer(s) 1806. The source/drain contact openings may be formed using appropriate photolithography and etch processes. One or more metals are deposited into the source/drain contact openings and over and on an upper surface of the first dielectric layer 1820. The one or more metals deposited into the source/drain contact openings form the drain metal contact 1902 and source metal contact 1904. The metal(s) may be deposited using an appropriate deposition process(es), such as CVD, physical vapor deposition (PVD), or the like. In some examples, the metal(s) may be respective conformal layer(s) in the source/drain contact openings that do not fill the source/drain contact openings, and in some examples, the metal(s) may fill the source/drain contact openings. The metal(s) over the upper surface of the first dielectric layer 1820 are patterned into the portions of the drain metal contact 1902 and source metal contact 1904 on the upper surface of the first dielectric layer 1820. The metal(s) may be patterned using appropriate photolithography and etch processes.

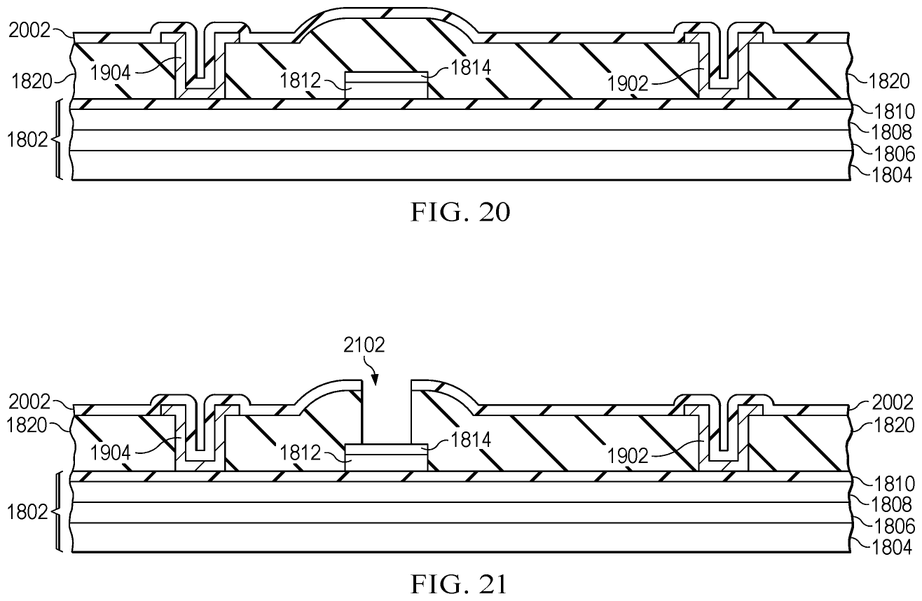

Referring to block 1710 of FIG. 17 and to FIG. 20, a second dielectric layer 2002 is formed over first dielectric layer 1820, the drain metal contact 1902, and the source metal contact 1904. The second dielectric layer 2002 is conformally over and on the first dielectric layer 1820, the drain metal contact 1902, and the source metal contact 1904. The second dielectric layer 2002 may be an etch stop layer that permits selectively etching one or more layers formed over the second dielectric layer 2002. In some examples, the second dielectric layer 2002 is or includes aluminum oxide (Al₂O₃). In other examples, the second dielectric layer 2002 may be or include a nitride, such as silicon nitride (SiN) or another one or more other dielectric materials. The second dielectric layer 2002 may be deposited using any appropriate deposition process, such as CVD, LPCVD, PECVD, atomic layer deposition (ALD), or the like.

Referring to block 1712 of FIG. 17 and to FIG. 21, a gate contact opening 2102 is formed through the second dielectric layer 2002 and the first dielectric layer 1820. In the illustrated example, where the silicon layer 1814 is implemented, the gate contact opening 2102 is to the silicon layer 1814. In other examples, the gate contact opening 2102 may be through the silicon layer 1814 to the gate layer 1812. In examples in which the silicon layer 1814 is not implemented, the gate contact opening 2102 may be to the gate layer 1812. The gate contact opening 2102 may be formed using appropriate photolithography and etch processes.

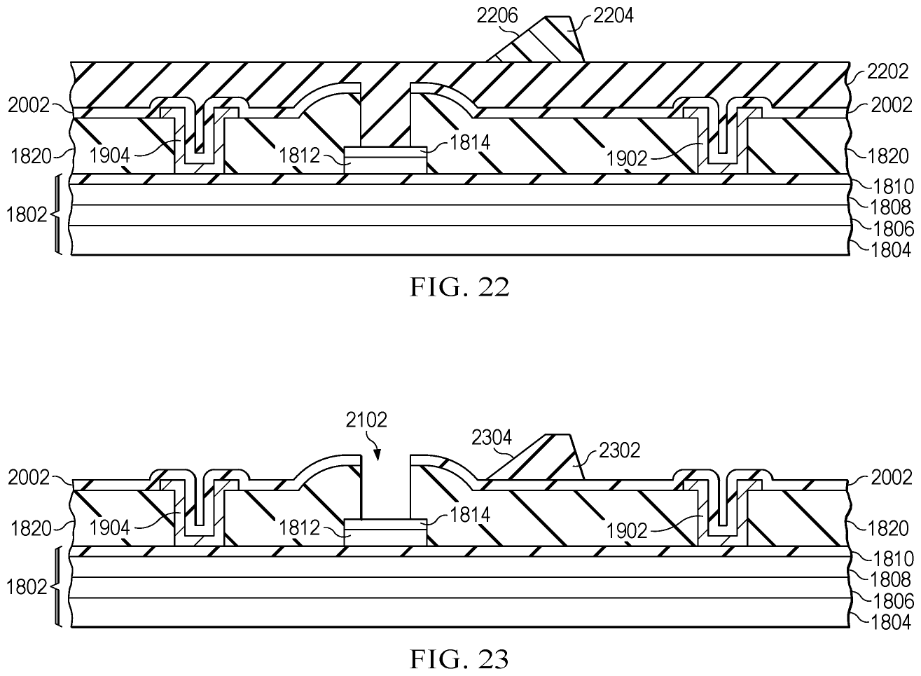

Referring to block 1714 of FIG. 17 and to FIG. 22, a dielectric material 2202 is deposited on and over the second dielectric layer 2002 and in the gate contact opening 2102. The dielectric material 2202 is to be patterned and structured with a slanted surface, as described subsequently. In some examples, the dielectric material 2202 is or includes silicon nitride (SiN); although in other examples, the dielectric material 2202 may be or include another one or more other dielectric materials. The dielectric material 2202 may be deposited using any appropriate deposition process, such as CVD, LPCVD, PECVD, ALD, or the like.

At block 1716, a photoresist 2204 is formed with a slanted surface 2206 using grayscale photolithography. The photoresist 2204 may be formed with the slanted surface 2206 as described above, including with respect to FIGS. 10, 15, and 16. The photoresist 2204 may be formed by depositing (e.g., by spin-on) a photoresist layer over and on the dielectric material 2202 and patterning the photoresist layer into the photoresist 2204 using grayscale photolithography. In the illustrated example, the slanted surface 2206 has a uniform slope throughout the slanted surface 2206.

Referring to block 1718 of FIG. 17 and to FIG. 23, the dielectric material 2202 is etched, using the photoresist 2204 as a mask, to form a dielectric structure 2302 having a slanted surface 2304. The dielectric material 2202 is etched as described above with respect to FIG. 11. The etching transfers a slope from the photoresist 2204 to the dielectric material 2202 to form the dielectric structure 2302 with the slanted surface 2304. The slanted surface 2304 has a uniform slope throughout the slanted surface 2304. An angle of the slanted surface 2304 may correspond to an angle of the slanted surface 2206 as described with respect to FIGS. 10 and 11.

The etch process may include multiple sub-processes. For example, a first sub-process may be an anisotropic etch that etches the dielectric material 2202 without significantly consuming the photoresist. Following the first sub-process, a second sub-process may be an anisotropic etch as described with respect to FIG. 11. Hence, for example, the first sub-process may remove the dielectric material 2202 from the gate contact opening 2102, while the second sub-process patterns the dielectric structure 2302 having the slanted surface 2304. In other examples, the photoresist 2204 may be patterned (e.g., with sufficient thickness and/or lateral dimension) such that the etch process as described with respect to FIG. 11 may over-etch the dielectric material 2202 (over-etch with respect to the level of the second dielectric layer 2002) to remove the dielectric material 2202 from the gate contact opening 2102 while permitting the dielectric structure 2302 to remain.

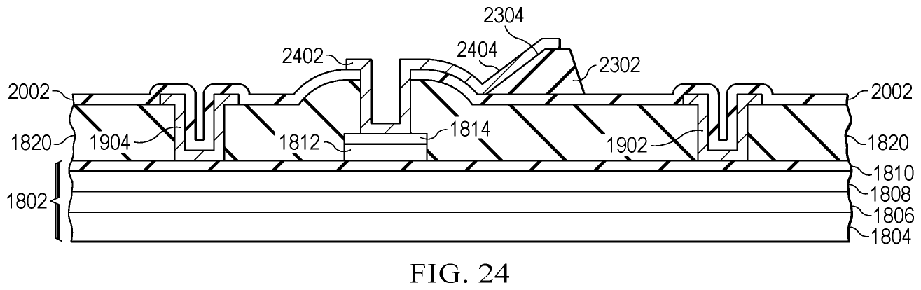

Referring to block 1720 and to FIG. 24, a gate metal contact 2402 and a first field plate portion 2404 are formed. The gate metal contact 2402, as illustrated, is conformally in the gate contact opening 2102 and contacts the silicon layer 1814 and/or gate layer 1812 (e.g., depending on the gate contact opening 2102 and/or presence of the silicon layer 1814 as described above). The first field plate portion 2404 is over and on the slanted surface 2304 of the dielectric structure 2302. In the illustrated example, the gate metal contact 2402 and the first field plate portion 2404 are in a same metal layer (e.g., METBGT layer). The gate metal contact 2402 and the first field plate portion 2404 are formed from a continuous portion of metal, which electrically couples the gate metal contact 2402 and the first field plate portion 2404. In other examples, the gate metal contact 2402 and the first field plate portion 2404 may be separate portions of metal. In such examples, the gate metal contact 2402 and the first field plate portion 2404 may be electrically coupled through another metal layer, such as by stacked metal vias and/or routing metals outside of the active area. The gate metal contact 2402 may include or be any appropriate metal. In some semiconductor devices, a gate metal contact may form a Schottky junction with the gate layer or may form an ohmic junction with the gate layer. As examples, when the gate layer is magnesium doped gallium nitride (GaN:Mg), metal that may form a Schottky junction with the gate layer may be or include titanium (Ti), titanium tungsten (TiW), titanium nitride (TiN), nickel (Ni), platinum (Pt), tantalum nitride (TaN), copper (Cu), tungsten (W), or alloys thereof. As examples, when the gate layer is magnesium doped gallium nitride (GaN:Mg), metal that may form an ohmic junction with the gate layer may be or include gold (Au), aluminum (Al), or alloys thereof. Examples of such alloys may include titanium tungsten aluminum (TiWAl) and titanium aluminum nitride (TiAlN).

One or more metals are deposited into the gate contact opening 2102 and over and on the second dielectric layer 2002 and the dielectric structure 2302. The one or more metals deposited into the gate contact opening 2102 form the gate metal contact 2402, and the one or more metals deposited on the slanted surface 2304 form the first field plate portion 2404. The metal(s) may be deposited using an appropriate deposition process(es), such as CVD, PVD, or the like. In some examples, the metal(s) may be respective conformal layer(s), e.g., in the gate contact opening 2102 that do not fill the gate contact opening 2102, and in some examples, the metal(s) may fill the gate contact opening 2102. The metal(s) over the second dielectric layer 2002 and the dielectric structure 2302 are patterned into the gate metal contact 2402 and the first field plate portion 2404. The metal(s) may be patterned using appropriate photolithography and etch processes.

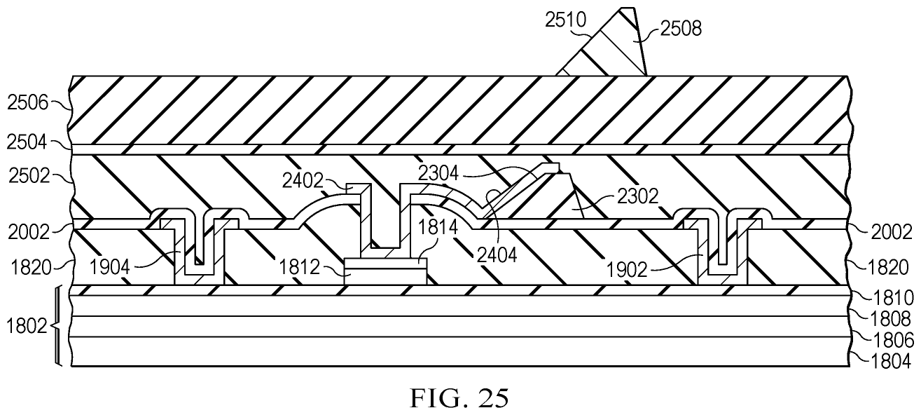

Referring to block 1722 and to FIG. 25, a third dielectric layer 2502 is formed over and on the second dielectric layer 2002, the gate metal contact 2402, and the first field plate portion 2404. The third dielectric layer 2502 may be an inter-layer dielectric layer (ILD). In some examples, the third dielectric layer 2502 is or includes silicon nitride (SiN); although in other examples, the third dielectric layer 2502 may be or include another one or more other dielectric materials. The third dielectric layer 2502 may be deposited using any appropriate deposition process, such as CVD, LPCVD, PECVD, or the like. The third dielectric layer 2502 may be planarized, such as by a chemical mechanical polish (CMP).

At block 1724, a fourth dielectric layer 2504 is formed over and on the third dielectric layer 2502. The fourth dielectric layer 2504 may be an etch stop layer that permits selectively etching one or more layers formed over the fourth dielectric layer 2504. In some examples, the fourth dielectric layer 2504 is or includes aluminum oxide (Al₂O₃). In other examples, the fourth dielectric layer 2504 may be or include a nitride, such as silicon nitride (SiN) or another one or more other dielectric materials. The fourth dielectric layer 2504 may be deposited using any appropriate deposition process, such as CVD, LPCVD, PECVD, ALD, or the like.

At block 1726, a dielectric material 2506 is deposited on and over the fourth dielectric layer 2504. The dielectric material 2506 is to be patterned and structured with a slanted surface, as described subsequently. In some examples, the dielectric material 2506 is or includes silicon nitride (SiN); although in other examples, the dielectric material 2506 may be or include another one or more other dielectric materials. The dielectric material 2506 may be deposited using any appropriate deposition process, such as CVD, LPCVD, PECVD, or the like.

At block 1728, a photoresist 2508 is formed with a slanted surface 2510 using grayscale photolithography. The photoresist 2508 may be formed with the slanted surface 2510 as described above, including with respect to FIGS. 10, 15, and 16. The photoresist 2508 may be formed by depositing (e.g., by spin-on) a photoresist layer over and on the dielectric material 2506 and patterning the photoresist layer into the photoresist 2508 using grayscale photolithography. In the illustrated example, the slanted surface 2510 has a uniform slope throughout the slanted surface 2510.

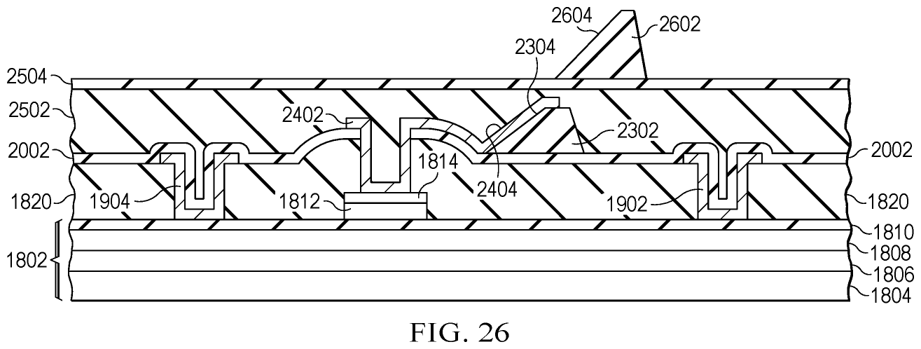

Referring to block 1730 of FIG. 17 and to FIG. 26, the dielectric material 2506 is etched, using the photoresist 2508 as a mask, to form a dielectric structure 2602 having a slanted surface 2604. The dielectric material 2506 is etched as described above with respect to FIG. 11. The etch transfers a slope from the photoresist 2508 to the dielectric material 2506 to form the dielectric structure 2602 with the slanted surface 2604. The slanted surface 2604 has a uniform slope throughout the slanted surface 2604. An angle of the slanted surface 2604 may correspond to an angle of the slanted surface 2510 as described with respect to FIGS. 10 and 11. The angle of the slanted surface 2604 may be less than, equal to, or greater than the angle of the slanted surface 2304.

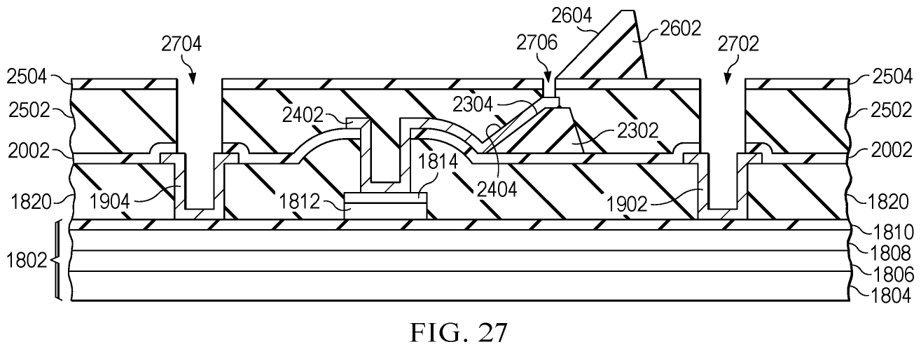

Referring to block 1732 of FIG. 17 and to FIG. 27, via openings 2702, 2704, 2706 are formed. The via opening 2702 is formed through the fourth dielectric layer 2504, the third dielectric layer 2502, and the second dielectric layer 2002 to the drain metal contact 1902. The via opening 2704 is formed through the fourth dielectric layer 2504, the third dielectric layer 2502, and the second dielectric layer 2002 to the source metal contact 1904. The via opening 2706 is formed through the fourth dielectric layer 2504 and the third dielectric layer 2502 to the first field plate portion 2404. The via openings 2702, 2704, 2706 may be formed using appropriate photolithography and etch processes.

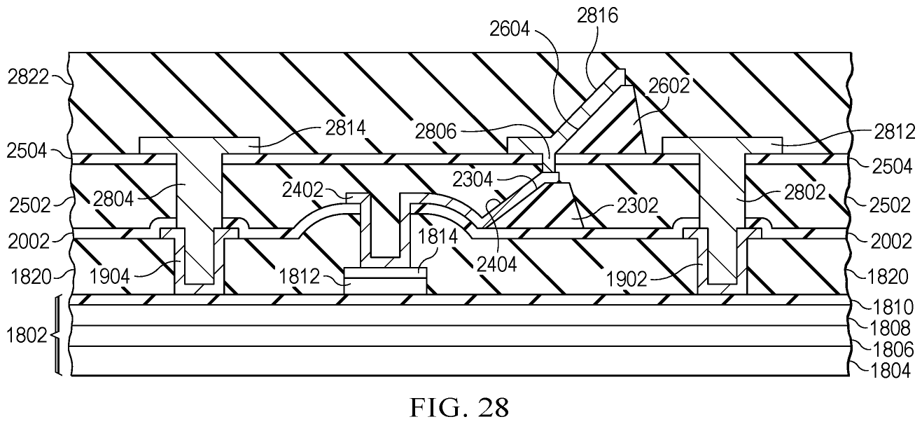

Referring to block 1734 of FIG. 17 and to FIG. 28, metal vias 2802, 2804, 2806, metal lines 2812, 2814, and a second field plate portion 2816 are formed. The metal via 2802 is in the via opening 2702 and contacts the drain metal contact 1902. The metal line 2812 is over and on the fourth dielectric layer 2504 and the metal via 2802, and the metal via 2802 extends from the metal line 2812 into the via opening 2702. The metal via 2804 is in the via opening 2704 and contacts the source metal contact 1904. The metal line 2814 is over and on the fourth dielectric layer 2504 and the metal via 2804, and the metal via 2804 extends from the metal line 2814 into the via opening 2704. The metal via 2806 is in the via opening 2706 and contacts the first field plate portion 2404. The second field plate portion 2816 is over and on the slanted surface 2604 of the dielectric structure 2602, the fourth dielectric layer 2504, and the metal via 2806, and the metal via 2806 extends from second field plate portion 2816 into the via opening 2706. Accordingly, the second field plate portion 2816 is electrically coupled to the first field plate portion 2404. In the illustrated example, the metal lines 2812, 2814, and the second field plate portion 2816 are in a same metal layer (e.g., MET1 layer).

The metal vias 2802, 2804, 2806 may each include (i) one or more metal-barrier and/or adhesion layers (e.g., titanium nitride (TiN), tantalum nitride (TaN), the like, or a combination thereof) conformally in a respective via opening and (ii) a fill metal (e.g., aluminum (Al), copper (Cu), tungsten (W), the like, or a combination thereof) over and/or on the metal-barrier and/or adhesion layer(s). The metal lines 2812, 2814 and the second field plate portion 2816 may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s). One or more metals are deposited in the via openings 2702, 2704, 2706 and over and on the fourth dielectric layer 2504 and the dielectric structure 2602. The metal(s) may be deposited using an appropriate deposition process(es), such as CVD, PVD, or the like. The metal(s) over the fourth dielectric layer 2504 and the dielectric structure 2602 are patterned into the metal lines 2812, 2814 and the second field plate portion 2816. The metal(s) may be patterned using appropriate photolithography and etching processes.

Metal vias, metal lines, and where appropriate, field plate portions formed in the MET1 layer or subsequently formed metal layers (e.g., MET2 layer, MET3 layer, etc.) may be formed as described above for forming the metal vias 2802, 2804, metal lines 2812, 2814, and second field plate portion 2816. The same or similar metal(s) may be used in the MET1 layer and subsequent metal layers. Any differences in processing would be readily understood from the figures and description herein.

At block 1736, a fifth dielectric layer 2822 is formed over and on the fourth dielectric layer 2504, the metal lines 2812, 2814, the second field plate portion 2816, and the dielectric structure 2602. The fifth dielectric layer 2822 may be an ILD. In some examples, the fifth dielectric layer 2822 is or includes silicon nitride (SiN); although in other examples, the fifth dielectric layer 2822 may be or include another one or more other dielectric materials. The fifth dielectric layer 2822 may be deposited using any appropriate deposition process, such as CVD, LPCVD, PECVD, or the like. The fifth dielectric layer 2822 may be planarized, such as by a CMP.

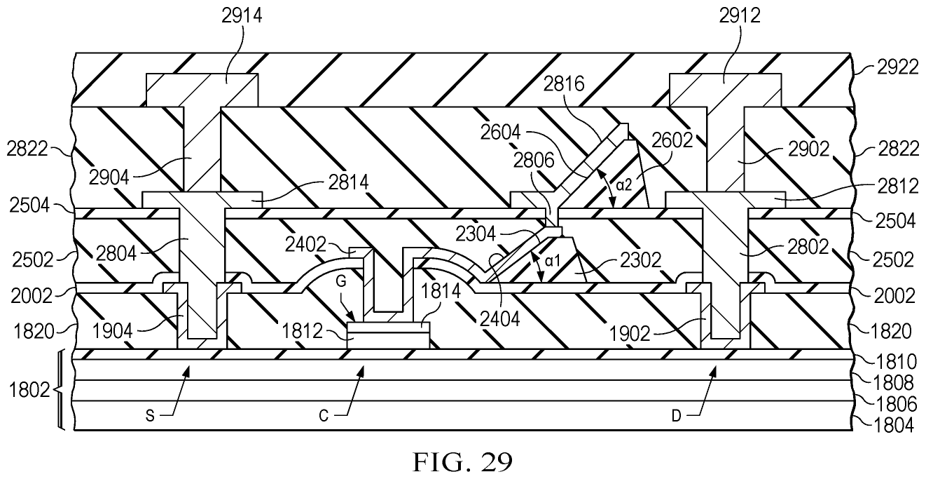

Referring to block 1738 and to FIG. 29, metal vias 2902, 2904 and metal lines 2912, 2914 are formed. The metal vias 2902, 2904 are in respective via openings through the fifth dielectric layer 2822. The metal via 2902 contacts the metal line 2812. The metal line 2912 is over and on the fifth dielectric layer 2822 and the metal via 2902, and the metal via 2902 extends from the metal line 2912 into the respective via opening. The metal via 2904 contacts the metal line 2814. The metal line 2914 is over and on the fifth dielectric layer 2822 and the metal via 2904, and the metal via 2904 extends from the metal line 2914 into the respective via opening. In the illustrated example, the metal lines 2912, 2914 are in a same metal layer (e.g., MET2 layer).

At block 1740, a sixth dielectric layer 2922 is formed over and on the fifth dielectric layer 2822 and the metal lines 2912, 2914. The sixth dielectric layer 2922 may be an ILD. In some examples, the sixth dielectric layer 2922 is or includes a silicon oxide-based material (such as a phosphosilicate glass (PSG) or a tetraethyl orthosilicate (TEOS) oxide) or silicon nitride (SiN); although in other examples, the sixth dielectric layer 2922 may be or include another one or more other dielectric materials. The sixth dielectric layer 2922 may be deposited using any appropriate deposition process, such as CVD, LPCVD, PECVD, or the like. The sixth dielectric layer 2922 may be planarized, such as by a CMP.

FIG. 29 illustrates a cross-sectional view of the semiconductor device 2900. The semiconductor device 2900 includes a source S, a channel C, a drain D, and a gate G. The gate G is or includes the gate layer 1812, which is on an upper surface of the semiconductor substrate 1802 (e.g., an upper surface of the barrier layer 1810). The channel C is in the channel layer 1808 in the semiconductor substrate 1802 and underlying the gate G. The channel C is laterally between the drain D and the source S, which are also in the channel layer 1808. The drain metal contact 1902 is electrically coupled to the drain D, and the source metal contact 1904 is electrically coupled to the source S. The gate metal contact 2402 is electrically coupled to the gate G (e.g., the gate layer 1812). The gate G and gate metal contact 2402 are laterally between the drain metal contact 1902 and the source metal contact 1904. The semiconductor device 2900 includes a field plate that includes the first field plate portion 2404 and the second field plate portion 2816, which are coupled together by the metal via 2806. The field plate extends from the drain-side of the gate G towards the drain metal contact 1902. The field plate portions 2404, 2816 each have a respective uniform slope with respect to the upper surface of the semiconductor substrate 1802, as illustrated by respective slope angles α₁, α₂ with respect to respective planes parallel to the upper surface of the semiconductor substrate 1802. In some examples, the slope of the first field plate portion 2404 may be smaller than the slope of the second field plate portion 2816 (e.g., such that α₁<α₂). In some examples, the slope of the first field plate portion 2404 may be greater than the slope of the second field plate portion 2816 (e.g., such that α₁>α₂). The first field plate portion 2404 abuts the gate metal contact 2402 (e.g., as a continuous metal pattern), and hence, the field plate is electrically coupled to the gate G (e.g., is a gate-coupled field plate).

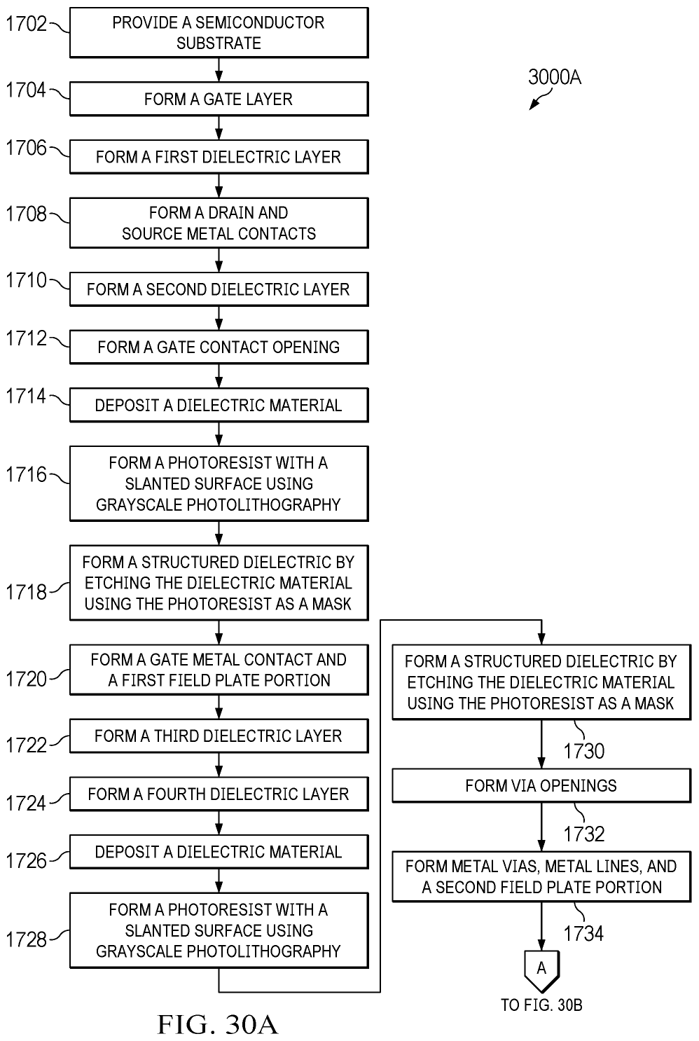

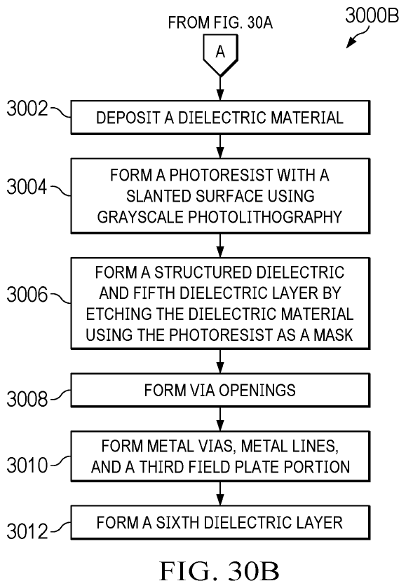

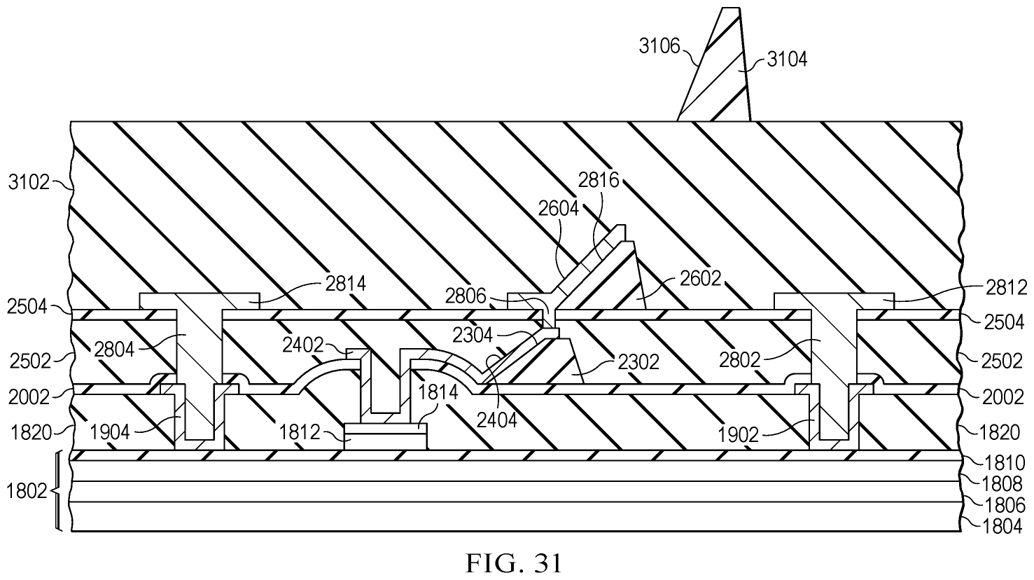

FIGS. 30A and 30B are a flowchart of a method 3000A, 3000B of manufacturing a semiconductor device (e.g., a HEMT) according to some examples. The method 3000A, 3000B of FIGS. 30A and 30B is illustrated by and described in the context of FIGS. 31 through 34, which illustrate cross-sectional views of the semiconductor device at various stages of manufacturing. The method 3000A, 3000B includes the processing of blocks 1702-1734, as described above with respect to FIG. 18 through FIG. 28.

Referring to block 3002 of FIG. 30B and to FIG. 31, after forming the metal vias 2802, 2804, 2806, metal lines 2812, 2814, and a second field plate portion 2816, a dielectric material 3102 is deposited on and over the fourth dielectric layer 2504, the dielectric structure 2602, the metal lines 2812, 2814, and the second field plate portion 2816. The dielectric material 3102 is to be patterned and structured with a slanted surface, as to be described subsequently. In some examples, the dielectric material 3102 is or includes silicon nitride (SiN); although in other examples, the dielectric material 3102 may be or include another one or more other dielectric materials. The dielectric material 3102 may be deposited using any appropriate deposition process, such as CVD, LPCVD, PECVD, or the like.

At block 3004, a photoresist 3104 is formed with a slanted surface 3106 using grayscale photolithography. The photoresist 3104 may be formed with the slanted surface 3106 as described above, including with respect to FIGS. 10, 15, and 16. The photoresist 3104 may be formed by depositing (e.g., by spin-on) a photoresist layer over and on the dielectric material 3102 and patterning the photoresist layer into the photoresist 3104 using grayscale photolithography. In the illustrated example, the slanted surface 3106 has a uniform slope throughout the slanted surface 3106.

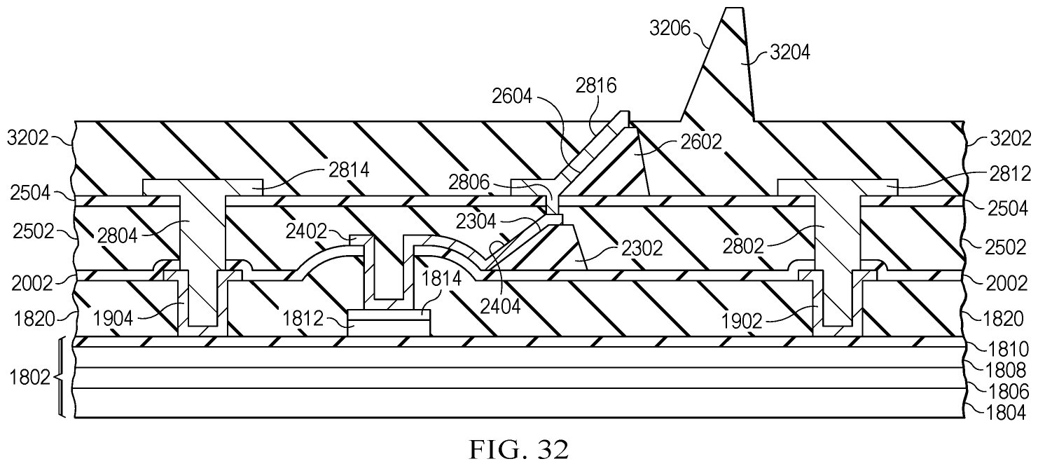

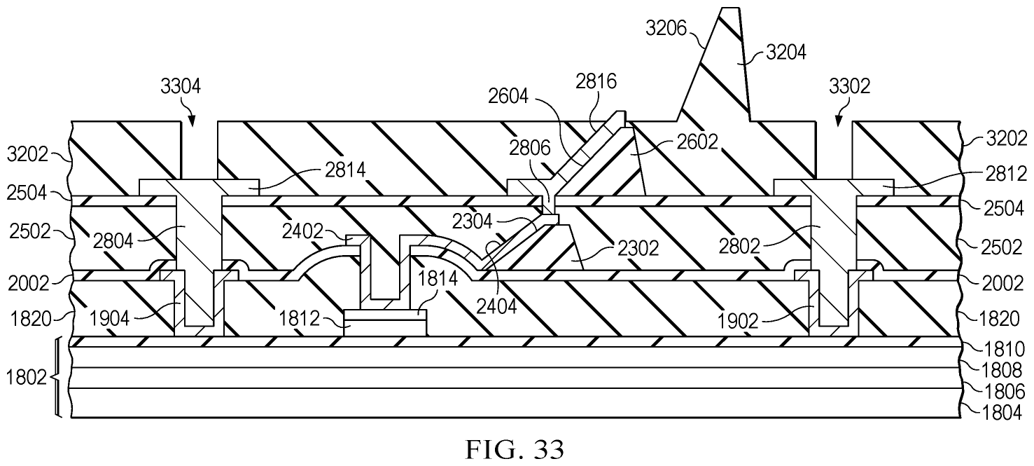

Referring to block 3006 of FIG. 30B and to FIG. 32, the dielectric material 3102 is etched, using the photoresist 3104 as a mask, to form a fifth dielectric layer 3202 and a dielectric structure 3204 having a slanted surface 3206. The dielectric material 3102 is etched as described above with respect to FIG. 11. The etch transfers a slope from the photoresist 3104 to the dielectric material 3102 to form the dielectric structure 3204 with the slanted surface 3206 and thins the dielectric material 3102 to form the fifth dielectric layer 3202. Hence, the fifth dielectric layer 3202 and the dielectric structure 3204, in the illustrated example, are a single dielectric component. The thinning of the dielectric material 3102 to form the fifth dielectric layer 3202 exposes an upper portion of the second field plate portion 2816. The slanted surface 3206 has a uniform slope throughout the slanted surface 3206. An angle of the slanted surface 3206 may correspond to an angle of the slanted surface 3106 as described with respect to FIGS. 10 and 11. The angle of the slanted surface 3206 may be less than, equal to, or greater than each of the angle of the slanted surface 2304 and the angle of the slanted surface 2604.

Referring to block 3008 of FIG. 30B and to FIG. 33, via openings 3302, 3304 are formed through the fifth dielectric layer 3202. The via opening 3302 is formed through the fifth dielectric layer 3202 to the metal line 2812. The via opening 3304 is formed through the fifth dielectric layer 3202 to the metal line 2814. The via openings 3302, 3304 may be formed using appropriate photolithography and etch processes.

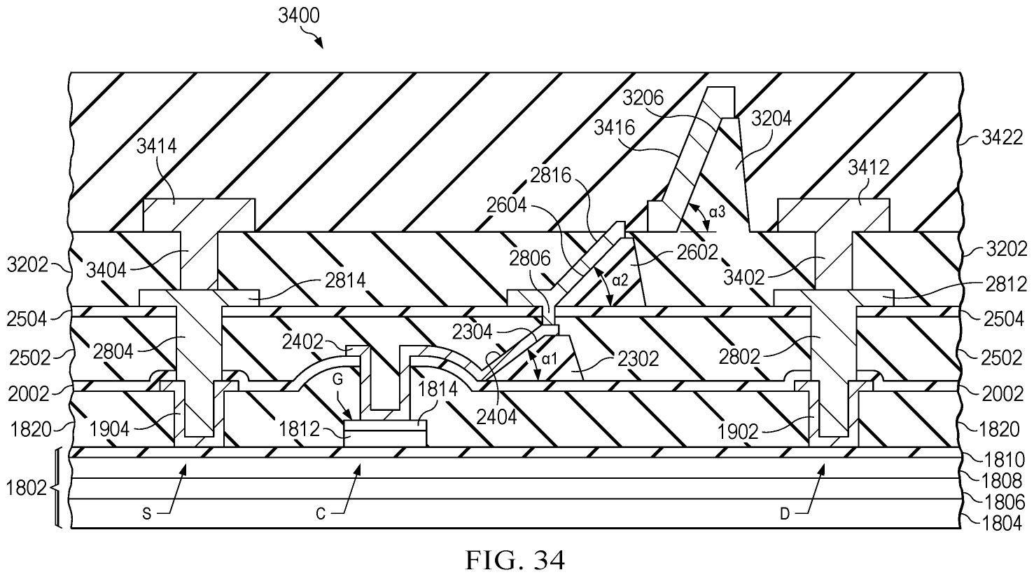

Referring to block 3010 of FIG. 30B and to FIG. 34, metal vias 3402, 3404, metal lines 3412, 3414, and a third field plate portion 3416 are formed. The metal via 3402 is in the via opening 3302 and contacts the metal line 2812. The metal line 3412 is over and on the fifth dielectric layer 3202 and the metal via 3402, and the metal via 3402 extends from the metal line 3412 into the via opening 3302. The metal via 3404 is in the via opening 3304 and contacts the metal line 2814. The metal line 3414 is over and on the fifth dielectric layer 3202 and the metal via 3404, and the metal via 3404 extends from the metal line 3414 into the via opening 3304. The third field plate portion 3416 is over and on the slanted surface 3206 of the dielectric structure 3204 and the fifth dielectric layer 3202. As illustrated, the third field plate portion 3416 is separated from the exposed portion of the second field plate portion 2816 by a gap. In such examples, the field plate portions 2816, 3416 may be electrically coupled through another metal layer to form respective portions of a field plate or may be electrically isolated from each other to form separate field plates. In some examples, if separated, the third field plate portion 3416 may be coupled to the source S (e.g., a source-coupled field plate). In some examples, the third field plate portion 3416 may be formed to be on and over the exposed portion of the second field plate portion 2816, which electrically couples the field plate portions 2816, 3416. In the illustrated example, the metal lines 3412, 3414, and the third field plate portion 3416 are in a same metal layer (e.g., MET2 layer).

At block 3012, a sixth dielectric layer 3422 is formed over and on the fifth dielectric layer 3202, the dielectric structure 3204, the metal lines 3412, 3414, and the third field plate portion 3416. The sixth dielectric layer 3422 may be an ILD. In some examples, the sixth dielectric layer 3422 is or includes silicon nitride (SiN); although in other examples, the sixth dielectric layer 3422 may be or include another one or more other dielectric materials. The sixth dielectric layer 3422 may be deposited using any appropriate deposition process, such as CVD, LPCVD, PECVD, or the like. The sixth dielectric layer 3422 may be planarized, such as by a CMP.

FIG. 34 illustrates a cross-sectional view of the manufactured semiconductor device 3400. The semiconductor device 3400 includes a source S, a channel C, a drain D, and a gate G. The gate G is or includes the gate layer 1812, which is on an upper surface of the semiconductor substrate 1802 (e.g., an upper surface of the barrier layer 1810). The channel C is in the channel layer 1808 in the semiconductor substrate 1802 and underlying the gate G. The channel C is laterally between the drain D and the source S, which are also in the channel layer 1808. The drain metal contact 1902 is electrically coupled to the drain D, and the source metal contact 1904 is electrically coupled to the source S. The gate metal contact 2402 is electrically coupled to the gate G (e.g., the gate layer 1812). The gate G and gate metal contact 2402 are laterally between the drain metal contact 1902 and the source metal contact 1904. The semiconductor device 3400 includes a first field plate and a second field plate. The first field plate includes the first field plate portion 2404 and the second field plate portion 2816, which are coupled together by the metal via 2806. The second field plate includes the third field plate portion 3416. The first field plate extends from the drain-side of the gate G towards the drain metal contact 1902. The field plate portions 2404, 2816, 3416 each have a respective uniform slope with respect to the upper surface of the semiconductor substrate 1802, as illustrated by respective slope angles α₁, α₂, α₃ with respect to respective planes parallel to the upper surface of the semiconductor substrate 1802. The slopes of the field plate portions 2404, 2816 may be as described above with respect to FIG. 29. In some examples, the slope of the third field plate portion 3416 may be greater than either or both of the slopes of the first field plate portion 2404 and the second field plate portion 2816. In some examples, the slope of the third field plate portion 3416 may be less than either or both of the slopes of the first field plate portion 2404 and the second field plate portion 2816. The first field plate portion 2404 abuts the gate metal contact 2402 (e.g., as a continuous metal pattern), and hence, the field plate is electrically coupled to the gate G (e.g., is a gate-coupled field plate). In some examples, the second field plate (e.g., the third field plate portion 3416) may be electrically coupled to the source S, such as through routing in a metal layer(s), and the second field plate may be a source-coupled field plate.

In some examples, the third field plate portion 3416 may be electrically coupled to the field plate portions 2404, 2816 to be another portion of the first field plate. For example, rather than having a gap between the upper portion of the second field plate portion 2816 protruding through the fifth dielectric layer 3202 and the lower portion of the third field plate portion 3416 on the fifth dielectric layer 3202, the lower portion of the third field plate portion 3416 may overlap and abut the upper portion of the second field plate portion 2816. In other examples, with the gap between the field plate portions 2816, 3416, routing in a metal layer(s) may electrically couple the third field plate portion 3416 to the field plate portions 2404, 2816.

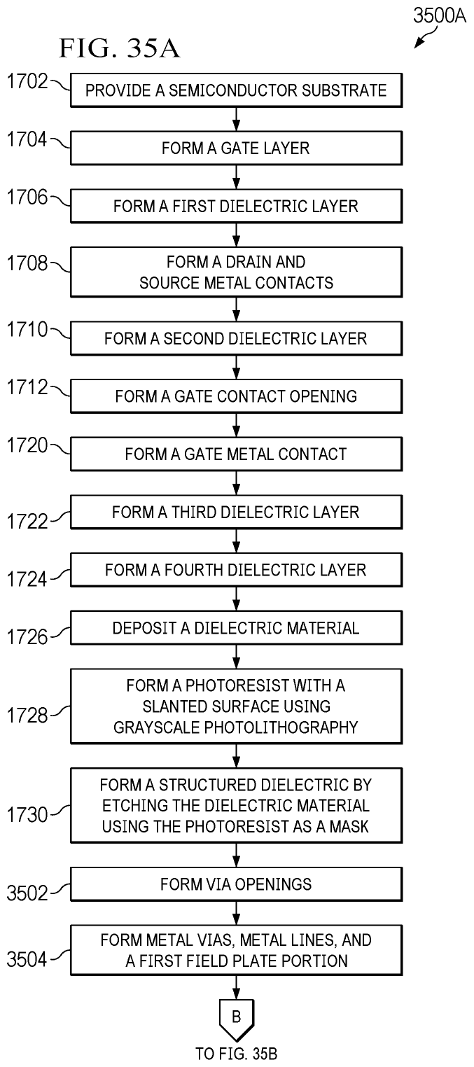

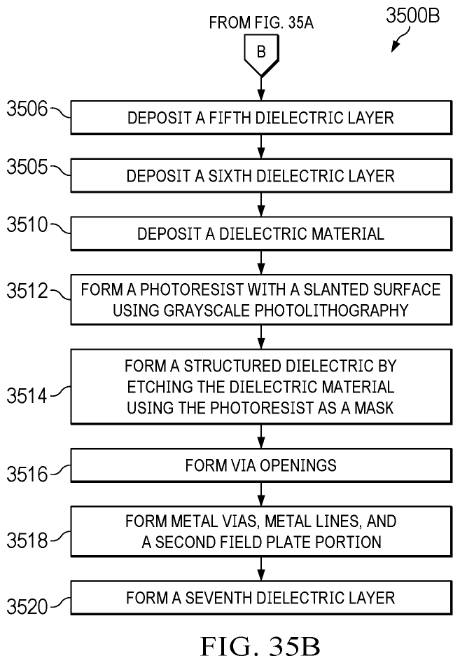

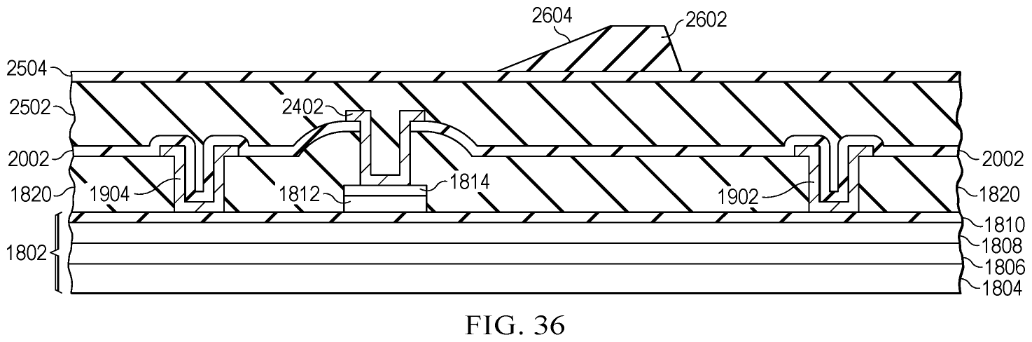

FIGS. 35A and 35B are a flowchart of a method 3500A, 3500B of manufacturing a semiconductor device (e.g., a HEMT) according to some examples. The method 3500A, 3500B of FIGS. 35A and 35B is illustrated by and described in the context of FIGS. 36 through 42, which illustrate cross-sectional views of the semiconductor device at various stages of manufacturing. The method 3500A, 3500B includes the processing of blocks 1702-1712, 1720-1730, as described above with respect to FIG. 18 through FIG. 26. Forming the dielectric structure 2302 and the first field plate portion 2404, and associated processing, is omitted (e.g., with the first field plate portion being omitted from block 1720), however. The resulting structure without the dielectric structure 2302 and the first field plate portion 2404 is illustrated in FIG. 36.

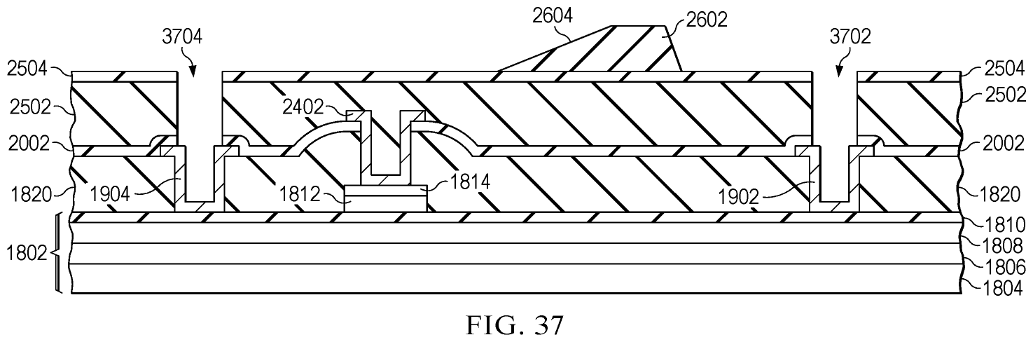

Referring to block 3502 of FIG. 35A and to FIG. 37, via openings 3702, 3704 are formed. The via opening 3702 is formed through the fourth dielectric layer 2504, the third dielectric layer 2502, and the second dielectric layer 2002 to the drain metal contact 1902. The via opening 3704 is formed through the fourth dielectric layer 2504, the third dielectric layer 2502, and the second dielectric layer 2002 to the source metal contact 1904. The via openings 3702, 3704 may be formed using appropriate photolithography and etch processes.

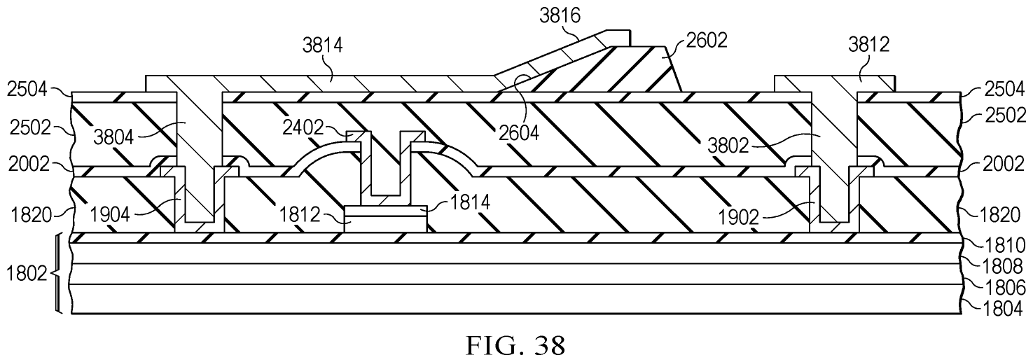

Referring to block 3504 of FIG. 35A and to FIG. 38, metal vias 3802, 3804, metal lines 3812, 3814, and a first field plate portion 3816 are formed. The metal via 3802 is in the via opening 3702 and contacts the drain metal contact 1902. The metal line 3812 is over and on the fourth dielectric layer 2504 and the metal via 3802, and the metal via 3802 extends from the metal line 3812 into the via opening 3702. The metal via 3804 is in the via opening 3704 and contacts the source metal contact 1904. The metal line 3814 is over and on the fourth dielectric layer 2504 and the metal via 3804, and the metal via 3804 extends from the metal line 3814 into the via opening 3704. The first field plate portion 3816 is over and on the slanted surface 2604 of the dielectric structure 2602 and the fourth dielectric layer 2504. As illustrated, the metal line 3814 and the first field plate portion 3816 are formed from a continuous portion of metal, which electrically couples the metal line 3814 and the first field plate portion 3816. Hence, the first field plate portion 3816 is electrically coupled to the source of the semiconductor device (e.g., HEMT). In the illustrated example, the metal lines 3812, 3814, and the first field plate portion 3816 are in a same metal layer (e.g., MET1 layer).

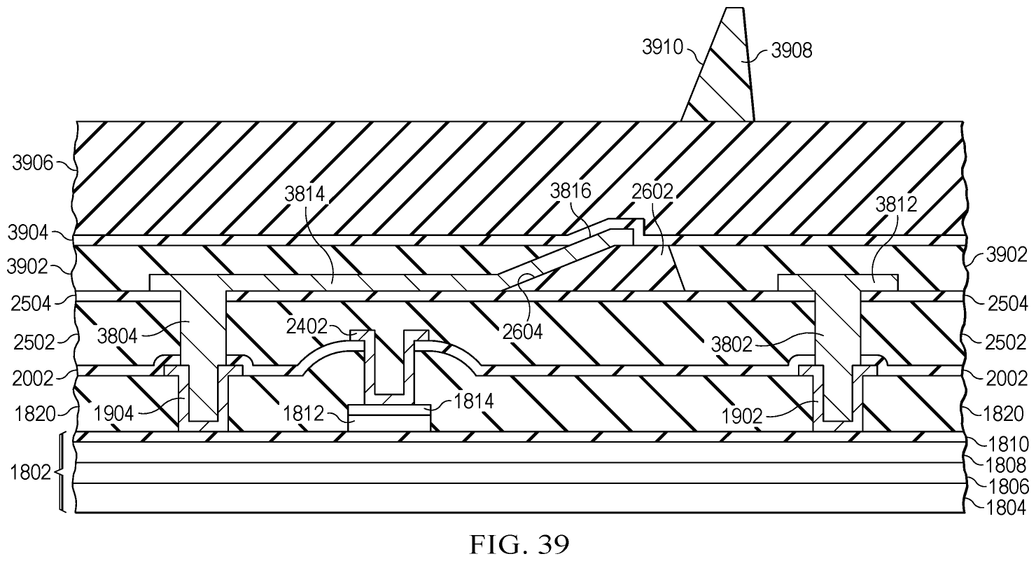

Referring to block 3506 of FIG. 35B and to FIG. 39, a fifth dielectric layer 3902 is formed over and on the fourth dielectric layer 2504, the dielectric structure 2602, the metal lines 3812, 3814, and the first field plate portion 3816. The fifth dielectric layer 3902 may be an ILD. In some examples, the fifth dielectric layer 3902 is or includes silicon nitride (SiN); although in other examples, the fifth dielectric layer 3902 may be or include another one or more other dielectric materials. The fifth dielectric layer 3902 may be deposited using any appropriate deposition process, such as CVD, LPCVD, PECVD, or the like. The fifth dielectric layer 3902 may be planarized, such as by an etch-back process. The etch-back process exposes an upper portion of the first field plate portion 3816.

At block 3508, a sixth dielectric layer 3904 is formed over and on the fifth dielectric layer 3902 and the exposed portion of the second field plate portion 2816. The sixth dielectric layer 3904 may be an etch stop layer that permits selectively etching one or more layers formed over the sixth dielectric layer 3904. In some examples, the sixth dielectric layer 3904 is or includes aluminum oxide (Al₂O₃). In other examples, the sixth dielectric layer 3904 may be or include a nitride, such as silicon nitride (SiN) or another one or more other dielectric materials. The sixth dielectric layer 3904 may be deposited using any appropriate deposition process, such as CVD, LPCVD, PECVD, ALD, or the like.

At block 3510, a dielectric material 3906 is deposited on and over the sixth dielectric layer 3904. The dielectric material 3906 is to be patterned and structured with a slanted surface, as described subsequently. In some examples, the dielectric material 3906 is or includes silicon nitride (SiN); although in other examples, the dielectric material 3906 may be or include another one or more other dielectric materials. The dielectric material 3906 may be deposited using any appropriate deposition process, such as CVD, LPCVD, PECVD, or the like.

At block 3512, a photoresist 3908 is formed with a slanted surface 3910 using grayscale photolithography. The photoresist 3908 may be formed with the slanted surface 3910 as described above, including with respect to FIGS. 10, 15, and 16. The photoresist 3908 may be formed by depositing (e.g., by spin-on) a photoresist layer over and on the dielectric material 3102 and patterning the photoresist layer into the photoresist 3908 using grayscale photolithography. In the illustrated example, the slanted surface 3910 has a uniform slope throughout the slanted surface 3910.

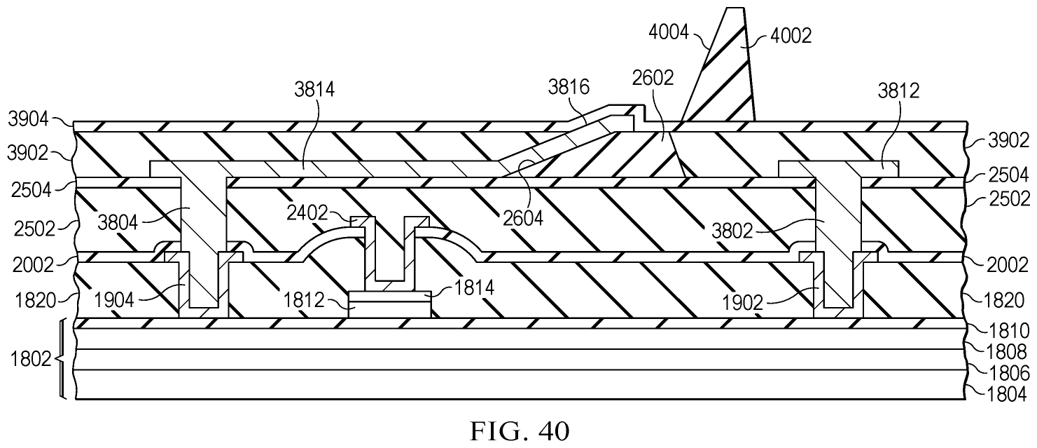

Referring to block 3514 of FIG. 35B and to FIG. 40, the dielectric material 3906 is etched, using the photoresist 3908 as a mask, to form a dielectric structure 4002 having a slanted surface 4004. The dielectric material 3906 is etched as described above with respect to FIG. 11. The etch transfers a slope from the photoresist 3908 to the dielectric material 3906 to form the dielectric structure 4002 with the slanted surface 4004. The slanted surface 4004 has a uniform slope throughout the slanted surface 4004. An angle of the slanted surface 4004 may correspond to an angle of the slanted surface 3910 as described with respect to FIGS. 10 and 11. The angle of the slanted surface 4004 may be less than, equal to, or greater than the angle of the slanted surface 2604.

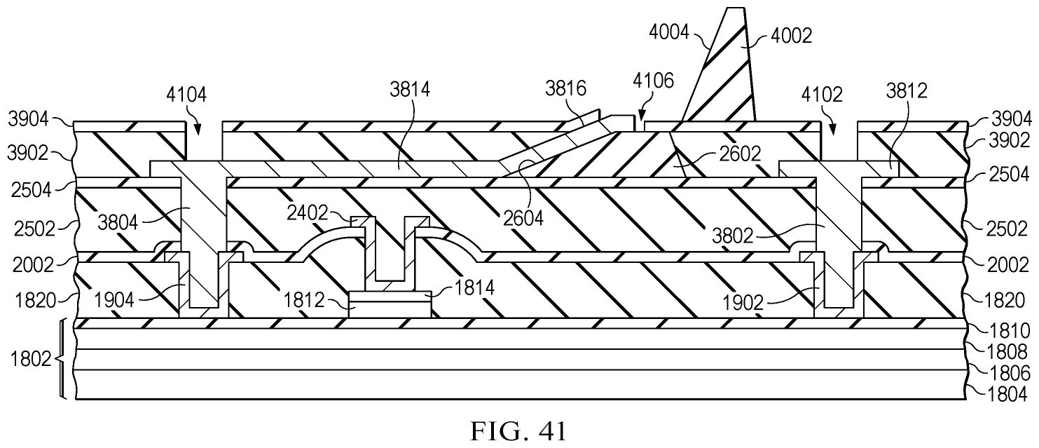

Referring to block 3516 of FIG. 35B and to FIG. 41, via openings 4102, 4104, 4106 are formed through the sixth dielectric layer 3904 and/or the fifth dielectric layer 3902. The via opening 4102 is formed through the sixth dielectric layer 3904 and the fifth dielectric layer 3902 to the metal line 3812. The via opening 4104 is formed through the sixth dielectric layer 3904 and the fifth dielectric layer 3902 to the metal line 3814. The via opening 4106 is formed through the sixth dielectric layer 3904 to the upper portion of the first field plate portion 3816, which was exposed through the fifth dielectric layer 3902. The via openings 4102, 4104, 4106 may be formed using appropriate photolithography and etch processes.

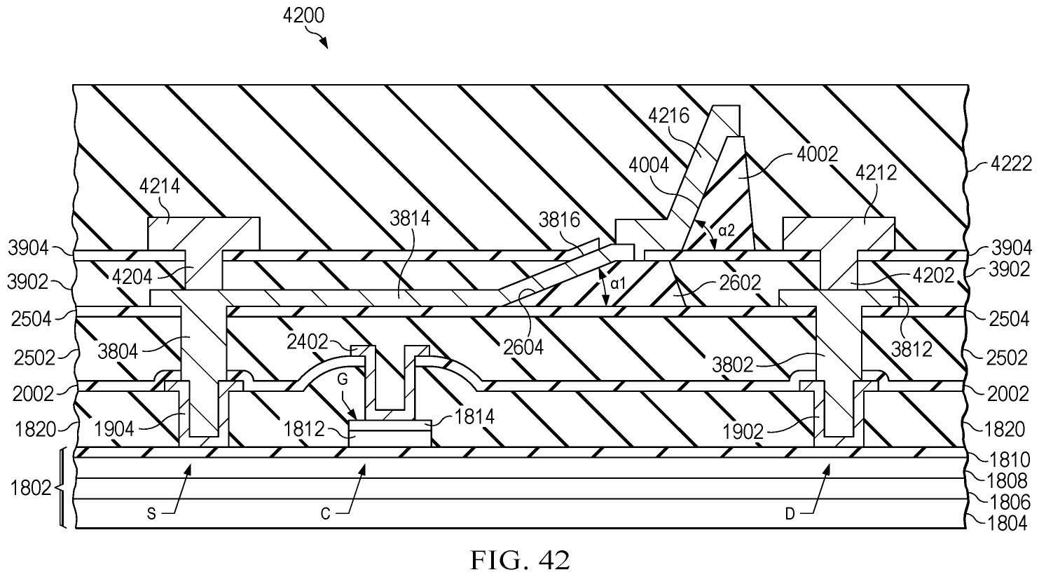

Referring to block 3518 of FIG. 35B and to FIG. 42, metal vias 4202, 4204, metal lines 4212, 4214, and a second field plate portion 4216 are formed. The metal via 4202 is in the via opening 4102 and contacts the metal line 3812. The metal line 4212 is over and on the sixth dielectric layer 3904 and the metal via 4202, and the metal via 4202 extends from the metal line 4212 into the via opening 4102. The metal via 4204 is in the via opening 4104 and contacts the metal line 3814. The metal line 4214 is over and on the sixth dielectric layer 3904 and the metal via 4204, and the metal via 4204 extends from the metal line 4214 into the via opening 4104. The second field plate portion 4216 is over and on the slanted surface 4004 of the dielectric structure 4002 and the sixth dielectric layer 3904 and is in the via opening 4106. As illustrated, the second field plate portion 4216 is on the first field plate portion 3816 by being disposed in the via opening 4106. In such examples, the field plate portions 3816, 4216 are electrically coupled to each other. In other examples, the second field plate portion 4216 may be electrically isolated from or electrically coupled to (through another metal layer) the first field plate portion 3816. In the illustrated example, the metal lines 4212, 4214, and the second field plate portion 4216 are in a same metal layer (e.g., MET2 layer).

At block 3520, a seventh dielectric layer 4222 is formed over and on the sixth dielectric layer 3904, the dielectric structure 4002, the metal lines 4212, 4214, and the second field plate portion 4216. The seventh dielectric layer 4222 may be an ILD. In some examples, the seventh dielectric layer 4222 is or includes a silicon oxide-based material (such as a PSG or a TEOS oxide) or silicon nitride (SiN); although in other examples, the seventh dielectric layer 4222 may be or include another one or more other dielectric materials. The seventh dielectric layer 4222 may be deposited using any appropriate deposition process, such as CVD, LPCVD, PECVD, or the like. The seventh dielectric layer 4222 may be planarized, such as by a CMP.

FIG. 42 illustrates a cross-sectional view of the manufactured semiconductor device 4200. The semiconductor device 4200 includes a source S, a channel C, a drain D, and a gate G. The gate G is or includes the gate layer 1812, which is on an upper surface of the semiconductor substrate 1802 (e.g., an upper surface of the barrier layer 1810). The channel C is in the channel layer 1808 in the semiconductor substrate 1802 and underlying the gate G. The channel C is laterally between the drain D and the source S, which are also in the channel layer 1808. The drain metal contact 1902 is electrically coupled to the drain D, and the source metal contact 1904 is electrically coupled to the source S. The gate metal contact 2402 is electrically coupled to the gate G (e.g., the gate layer 1812). The gate G and gate metal contact 2402 are laterally between the drain metal contact 1902 and the source metal contact 1904. The semiconductor device 4200 includes a field plate that includes the first field plate portion 3816 and the second field plate portion 4216, which are coupled together by the second field plate portion 4216 overlapping and contacting the first field plate portion 3816. The field plate extends from the drain-side of the gate G towards the drain metal contact 1902. The field plate portions 3816, 4216 each have a respective uniform slope with respect to the upper surface of the semiconductor substrate 1802, as illustrated by respective slope angles α₁, α₂ with respect to respective planes parallel to the upper surface of the semiconductor substrate 1802. In some examples, the slope of the first field plate portion 3816 may be smaller than the slope of the second field plate portion 4216 (e.g., such that α₁<α₂). In some examples, the slope of the first field plate portion 3816 may be greater than the slope of the second field plate portion 4216 (e.g., such that α₁>α₂). The field plate is electrically coupled through the metal line 3814, metal via 3804, and source metal contact 1904 to the source S (e.g., is a source-coupled field plate).

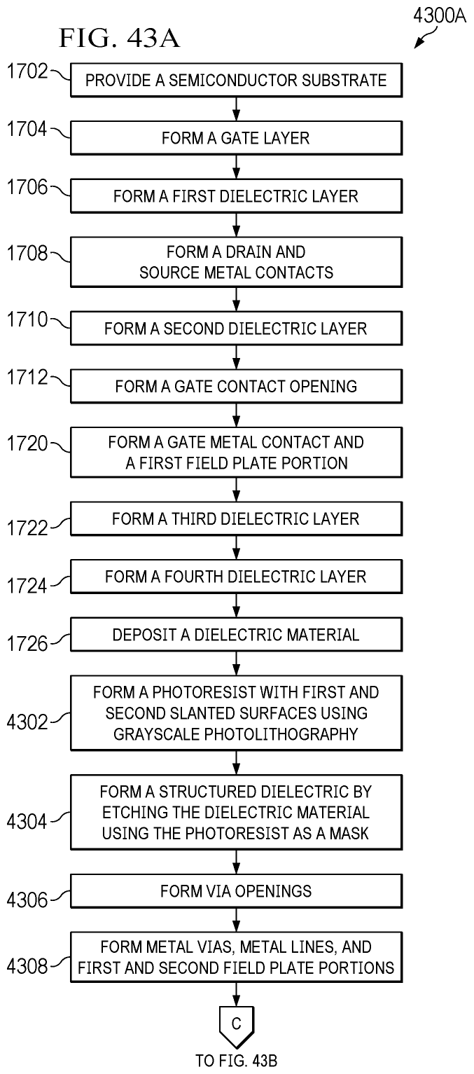

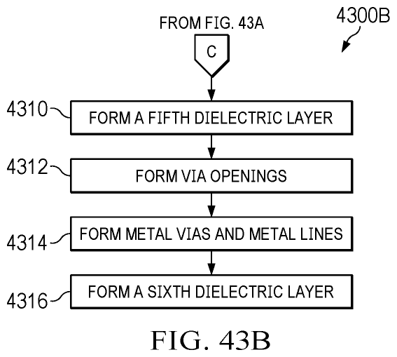

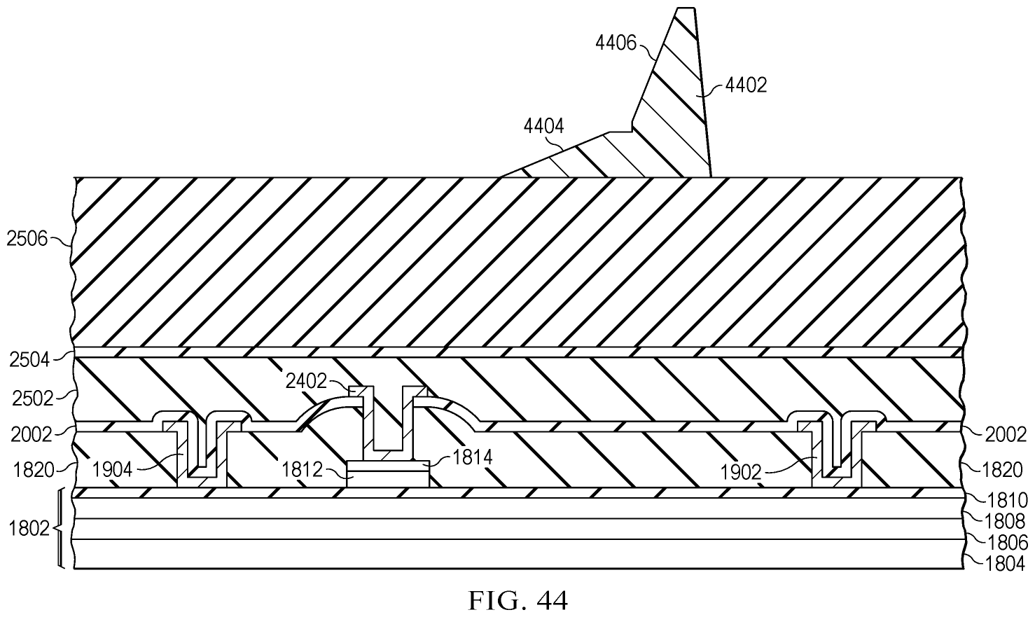

FIGS. 43A and 43B are a flowchart of a method 4300A, 4300B of manufacturing a semiconductor device (e.g., a HEMT) according to some examples. The method 4300A, 4300B of FIGS. 43A and 43B is illustrated by and described in the context of FIGS. 44 through 49, which illustrate cross-sectional views of the semiconductor device at various stages of manufacturing. The method 4300A, 4300B includes the processing of blocks 1702-1712, 1720-1726, as described above with respect to FIG. 18 through FIG. 24 and forming the dielectric layers 2502, 2504 and dielectric material 2506 in FIG. 25. Forming the dielectric structure 2302 and the first field plate portion 2404, and associated processing, is omitted, however. The resulting structure without the dielectric structure 2302 and the first field plate portion 2404 is illustrated in FIG. 44.

Referring to block 4302 of FIG. 43A and to FIG. 44, a photoresist 4402 is formed with a first slanted surface 4404 and a second slanted surface 4406 using grayscale photolithography. The photoresist 4402 may be formed with the slanted surfaces 4404, 4406 as described above, including with respect to FIGS. 13, 15, and 16. The photoresist 4402 may be formed by depositing (e.g., by spin-on) a photoresist layer over and on the dielectric material 2506 and patterning the photoresist layer into the photoresist 4402 using grayscale photolithography. In the illustrated example, each slanted surface 4404, 4406 has a respective uniform slope throughout the respective slanted surface 4404, 4406. Respective angles formed by the slanted surfaces 4404, 4406 are different. A transition surface may be between the slanted surfaces 4404, 4406, as described above with respect to FIG. 13.

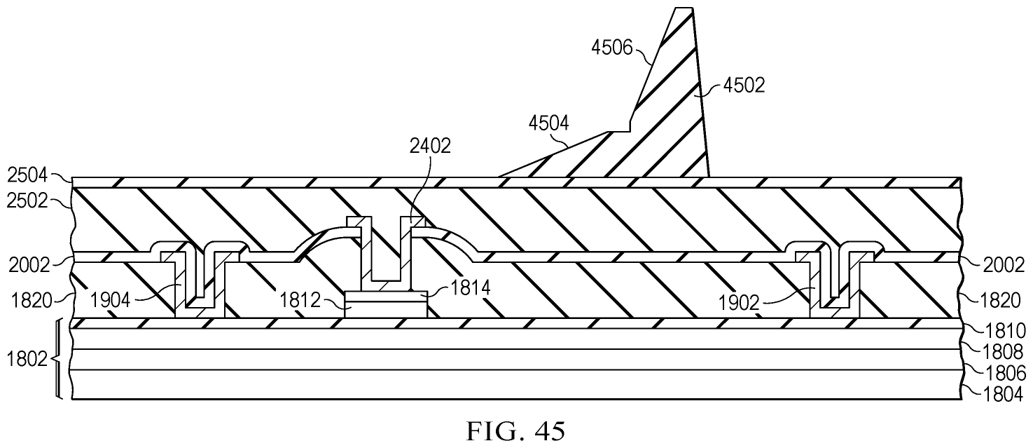

Referring to block 4304 of FIG. 43A and to FIG. 45, the dielectric material 2506 is etched, using the photoresist 4402 as a mask, to form a dielectric structure 4502 having a first slanted surface 4504 and a second slanted surface 4506. The dielectric material 2506 is etched as described above with respect to FIGS. 11 and 14. The etch transfers slopes from the photoresist 4402 to the dielectric material 2506 to form the dielectric structure 4502 with the slanted surfaces 4504, 4506. Each slanted surface 4504, 4506 has a uniform slope throughout the respective slanted surface 4504, 4506. An angle of the slanted surface 4504 may correspond to an angle of the slanted surface 4404 as described with respect to FIGS. 13 and 14, and an angle of the slanted surface 4506 may correspond to an angle of the slanted surface 4406 as described with respect to FIGS. 13 and 14.

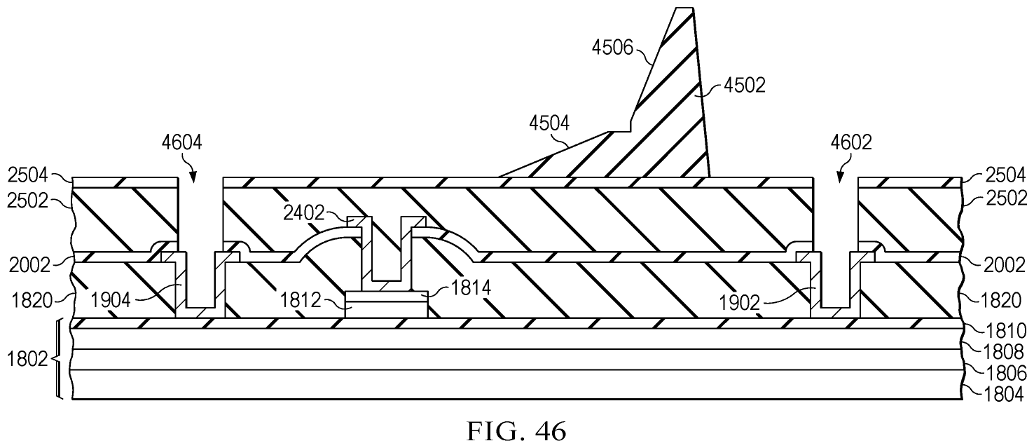

Referring to block 4306 of FIG. 43A and to FIG. 46, via openings 4602, 4604 are formed. The via opening 4602 is formed through the fourth dielectric layer 2504, the third dielectric layer 2502, and the second dielectric layer 2002 to the drain metal contact 1902. The via opening 4604 is formed through the fourth dielectric layer 2504, the third dielectric layer 2502, and the second dielectric layer 2002 to the source metal contact 1904. The via openings 4602, 4604 may be formed using appropriate photolithography and etch processes.

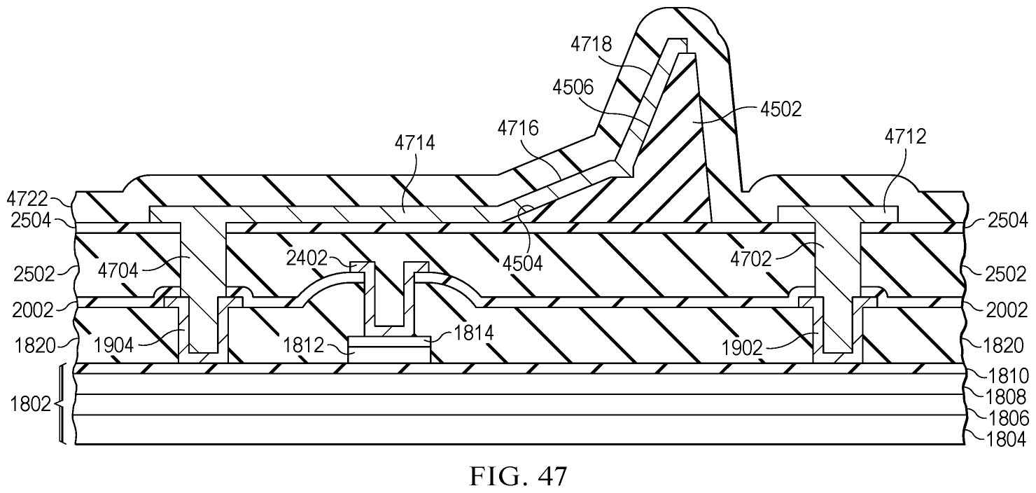

Referring to block 4308 of FIG. 43A and to FIG. 47, metal vias 4702, 4704, metal lines 4712, 4714, and a field plate including a first field plate portion 4716 and a second field plate portion 4718 are formed. The metal via 4702 is in the via opening 4602 and contacts the drain metal contact 1902. The metal line 4712 is over and on the fourth dielectric layer 2504 and the metal via 4702, and the metal via 4702 extends from the metal line 4712 into the via opening 4602. The metal via 4704 is in the via opening 4604 and contacts the source metal contact 1904. The metal line 4714 is over and on the fourth dielectric layer 2504 and the metal via 4704, and the metal via 4704 extends from the metal line 4714 into the via opening 4604. The first field plate portion 4716 is over and on the first slanted surface 4504 of the dielectric structure 4502 and the fourth dielectric layer 2504, and the second field plate portion 4718 is over and on the second slanted surface 4506 of the dielectric structure 4502. As illustrated, the metal line 4714 and the field plate (including the first field plate portion 4716 and the second field plate portion 4718) are formed from a continuous portion of metal, which electrically couples the metal line 4714 and the field plate (including the first field plate portion 4716 and the second field plate portion 4718). Hence, the field plate is electrically coupled to the source of the semiconductor device (e.g., HEMT). In the illustrated example, the metal lines 4712, 4714, and the field plate are in a same metal layer (e.g., MET1 layer).

At block 4310 of FIG. 43B, a fifth dielectric layer 4722 is formed conformally over and on the fourth dielectric layer 2504, the dielectric structure 4502, the metal lines 4712, 4714, and the field plate including the field plate portions 4716, 4718. The fifth dielectric layer 4722 may be an ILD. In some examples, the fifth dielectric layer 4722 is or includes silicon nitride (SiN); although in other examples, the fifth dielectric layer 4722 may be or include another one or more other dielectric materials. The fifth dielectric layer 4722 may be deposited using any appropriate deposition process, such as CVD, LPCVD, PECVD, or the like.

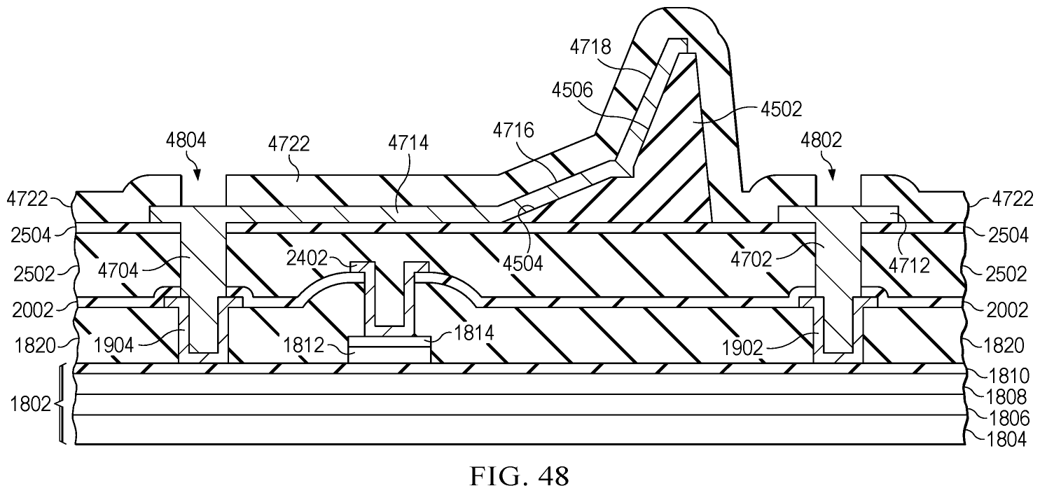

Referring to block 4312 of FIG. 43B and to FIG. 48, via openings 4802, 4804 are formed through fifth dielectric layer 4722. The via opening 4802 is formed through the fifth dielectric layer 4722 to the metal line 4712. The via opening 4804 is formed through the fifth dielectric layer 4722 to the metal line 4714. The via openings 4802, 4804 may be formed using appropriate photolithography and etch processes.

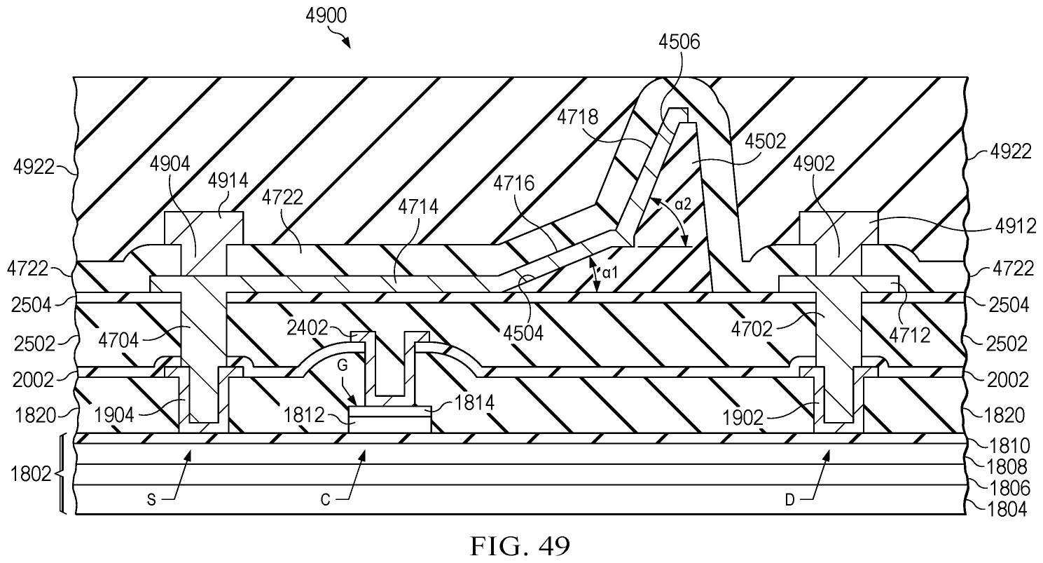

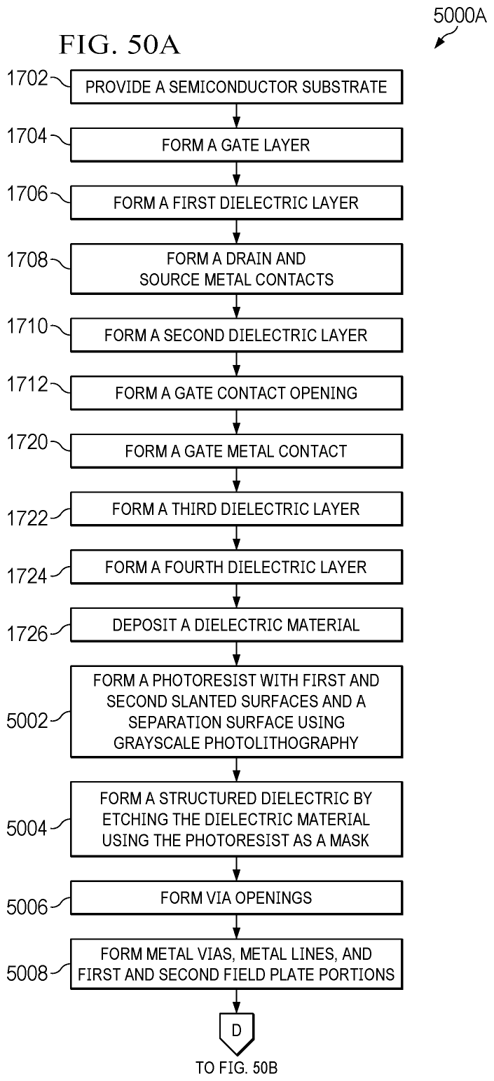

Referring to block 4314 of FIG. 43B and to FIG. 49, metal vias 4902, 4904 and metal lines 4912, 4914 are formed. The metal via 4902 is in the via opening 4802 and contacts the metal line 4712. The metal line 4912 is over and on the fifth dielectric layer 4722 and the metal via 4902, and the metal via 4902 extends from the metal line 4912 into the via opening 4802. The metal via 4904 is in the via opening 4804 and contacts the metal line 4714. The metal line 4914 is over and on the fifth dielectric layer 4722 and the metal via 4904, and the metal via 4904 extends from the metal line 4914 into the via opening 4804. In the illustrated example, the metal lines 4912, 4914 are in a same metal layer (e.g., MET2 layer).

At block 4316, a sixth dielectric layer 4922 is formed over and on the fifth dielectric layer 4722 and the metal lines 4912, 4914. The sixth dielectric layer 4922 may be an ILD. In some examples, the sixth dielectric layer 4922 is or includes a silicon oxide-based material (such as a PSG or a TEOS oxide) or silicon nitride (SiN); although in other examples, the sixth dielectric layer 4922 may be or include another one or more other dielectric materials. The sixth dielectric layer 4922 may be deposited using any appropriate deposition process, such as CVD, LPCVD, PECVD, or the like. The sixth dielectric layer 4922 may be planarized, such as by a CMP.

FIG. 49 illustrates a cross-sectional view of the manufactured semiconductor device 4900. The semiconductor device 4900 includes a source S, a channel C, a drain D, and a gate G. The gate G is or includes the gate layer 1812, which is on an upper surface of the semiconductor substrate 1802 (e.g., an upper surface of the barrier layer 1810). The channel C is in the channel layer 1808 in the semiconductor substrate 1802 and underlying the gate G. The channel C is laterally between the drain D and the source S, which are also in the channel layer 1808. The drain metal contact 1902 is electrically coupled to the drain D, and the source metal contact 1904 is electrically coupled to the source S. The gate metal contact 2402 is electrically coupled to the gate G (e.g., the gate layer 1812). The gate G and gate metal contact 2402 are laterally between the drain metal contact 1902 and the source metal contact 1904. The semiconductor device 4900 includes a field plate that includes the first field plate portion 4716 and the second field plate portion 4718, which are coupled together by the second field plate portion 4718 continuously extending from the first field plate portion 4716. The field plate extends from the drain-side of the gate G towards the drain metal contact 1902. The field plate portions 4716, 4718 each have a respective uniform slope with respect to the upper surface of the semiconductor substrate 1802, as illustrated by respective slope angles α₁, α₂ with respect to respective planes parallel to the upper surface of the semiconductor substrate 1802. In some examples, the slope of the first field plate portion 4716 may be smaller than the slope of the second field plate portion 4718 (e.g., such that α₁<α₂). In some examples, the slope of the first field plate portion 4716 may be greater than the slope of the second field plate portion 4718 (e.g., such that α₁>α₂). The field plate is electrically coupled through the metal line 4714, metal via 4704, and source metal contact 1904 to the source S (e.g., is a source-coupled field plate).

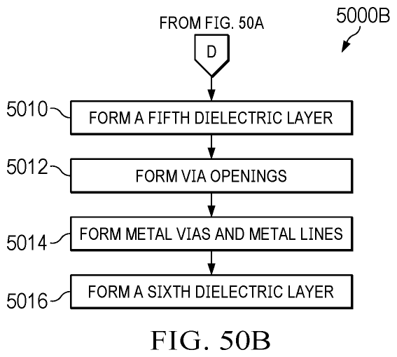

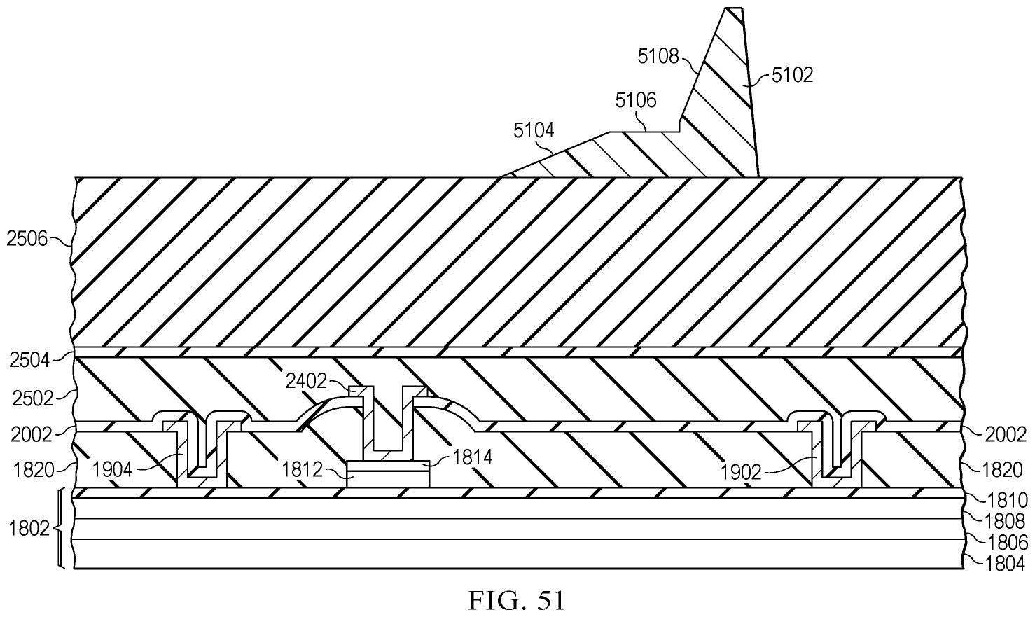

FIGS. 50A and 50B are a flowchart of a method 5000A, 5000B of manufacturing a semiconductor device (e.g., a HEMT) according to some examples. The method 5000A, 5000B of FIGS. 50A and 50B is illustrated by and described in the context of FIGS. 51 through 56, which illustrate cross-sectional views of the semiconductor device at various stages of manufacturing. The method 5000A, 5000B includes the processing of blocks 1702-1712, 1720-1726, as described above with respect to FIG. 18 through FIG. 24 and forming the dielectric layers 2502, 2504 and dielectric material 2506 in FIG. 25. Forming the dielectric structure 2302 and the first field plate portion 2404, and associated processing, is omitted, however. The resulting structure without the dielectric structure 2302 and the first field plate portion 2404 is illustrated in FIG. 51.

Referring to block 5002 of FIG. 50A and to FIG. 51, a photoresist 5102 is formed with a first slanted surface 5104, a separation surface 5106, and a second slanted surface 5108 using grayscale photolithography. The photoresist 5102 may be formed with the slanted surfaces 5104, 5108 and separation surface 5106 as described above, including with respect to FIGS. 13, 15, and 16. The photoresist 5102 may be formed by depositing (e.g., by spin-on) a photoresist layer over and on the dielectric material 2506 and patterning the photoresist layer into the photoresist 5102 using grayscale photolithography. In the illustrated example, each slanted surface 5104, 5108 has a uniform slope throughout the respective slanted surface 5104, 5108. Respective angles formed by the slanted surfaces 5104, 5108 are different. The separation surface 5106 is between the slanted surfaces 5104, 5108. The first slanted surface 5104 extends from the top surface of the dielectric material 2506 to the separation surface 5106, and the second slanted surface 5108 extends from the separation surface 5106 in a direction away from the first slanted surface 5104. The separation surface 5106 is parallel to the top surface of the dielectric material 2506. In other examples, the separation surface 5106 may be any other transition surface, such as described above with respect to FIG. 13.

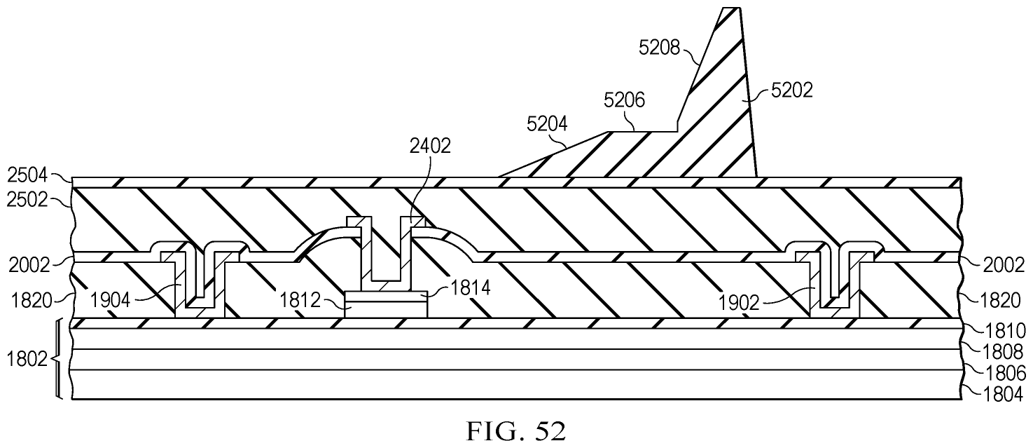

Referring to block 5004 of FIG. 50A and to FIG. 52, the dielectric material 2506 is etched, using the photoresist 5102 as a mask, to form a dielectric structure 5202 having a first slanted surface 5204, a separation surface 5206, and a second slanted surface 5208. The dielectric material 2506 is etched as described above with respect to FIGS. 11 and 14. The etch transfers slopes from the photoresist 5102 to the dielectric material 2506 to form the dielectric structure 5202 with the slanted surfaces 5204, 5208 and separation surface 5206. Each slanted surface 5204, 5208 has a uniform slope throughout the respective slanted surface 5204, 5208. An angle of the slanted surface 5204 may correspond to an angle of the slanted surface 5104 as described with respect to FIGS. 13 and 14, and an angle of the slanted surface 5208 may correspond to an angle of the slanted surface 5108 as described with respect to FIGS. 13 and 14. The separation surface 5206 is between the slanted surfaces 5204, 5208. The first slanted surface 5204 extends from the top surface of the fourth dielectric layer 2504 to the separation surface 5206, and the second slanted surface 5208 extends from the separation surface 5206 in a direction away from the first slanted surface 5204. The separation surface 5206 is parallel to the top surface of the fourth dielectric layer 2504.

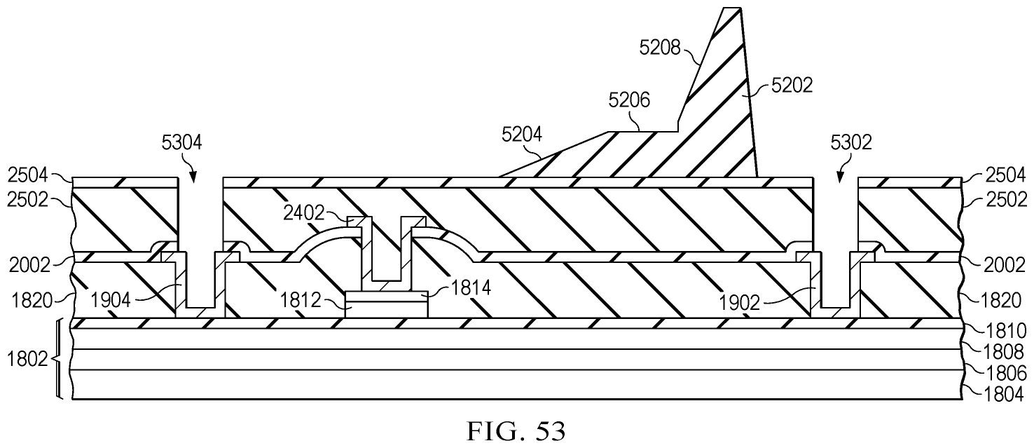

Referring to block 5006 of FIG. 50A and to FIG. 53, via openings 5302, 5304 are formed. The via opening 5302 is formed through the fourth dielectric layer 2504, the third dielectric layer 2502, and the second dielectric layer 2002 to the drain metal contact 1902. The via opening 5304 is formed through the fourth dielectric layer 2504, the third dielectric layer 2502, and the second dielectric layer 2002 to the source metal contact 1904. The via openings 5302, 5304 may be formed using appropriate photolithography and etch processes.

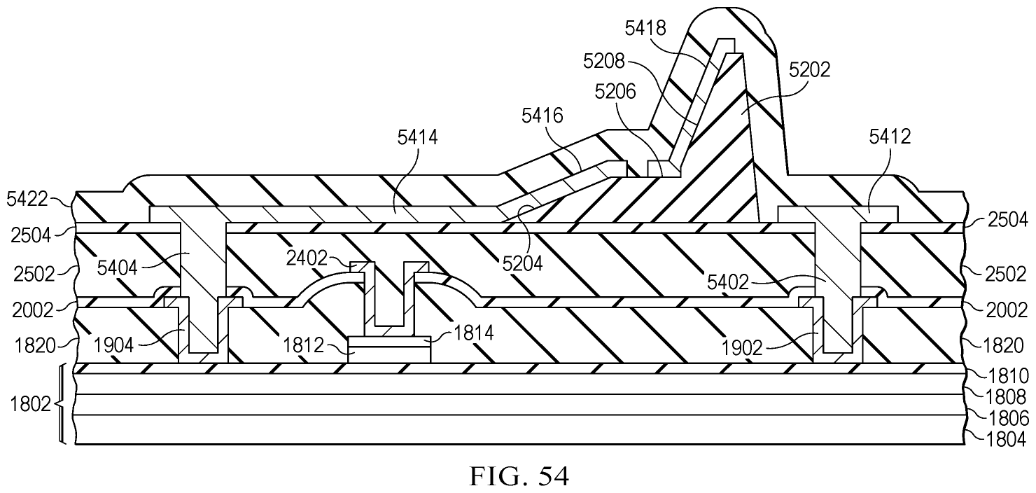

Referring to block 5008 of FIG. 50A and to FIG. 54, metal vias 5402, 5404, metal lines 5412, 5414, a first field plate portion 5416, and a second field plate portion 5418 are formed. The metal via 5402 is in the via opening 5302 and contacts the drain metal contact 1902. The metal line 5412 is over and on the fourth dielectric layer 2504 and the metal via 5402, and the metal via 5402 extends from the metal line 5412 into the via opening 5302. The metal via 5404 is in the via opening 5304 and contacts the source metal contact 1904. The metal line 5414 is over and on the fourth dielectric layer 2504 and the metal via 5404, and the metal via 5404 extends from the metal line 5414 into the via opening 5304. The first field plate portion 5416 is over and on the first slanted surface 5204 of the dielectric structure 5202 and the fourth dielectric layer 2504, and the second field plate portion 5418 is over and on the second slanted surface 5208 of the dielectric structure 5202. As illustrated, the metal line 5414 and the first field plate portion 5416 are formed from a continuous portion of metal, which electrically couples the metal line 5414 and the first field plate portion 5416. Hence, the first field plate portion 5416 is electrically coupled to the source of the semiconductor device (e.g., HEMT). The second field plate portion 5418 is separated from the first field plate portion 5416 by a gap (e.g., at the separation surface 5106) and is electrically isolated from the first field plate portion 5416. In the illustrated example, the metal lines 5412, 5414, and the field plate portions 5416, 5418 are in a same metal layer (e.g., MET1 layer).

At block 5010 of FIG. 50B, a fifth dielectric layer 5422 is formed conformally over and on the fourth dielectric layer 2504, the metal lines 5412, 5414, and the field plate portions 5416, 5418. The fifth dielectric layer 5422 may be an ILD. In some examples, the fifth dielectric layer 5422 is or includes silicon nitride (SiN); although in other examples, the fifth dielectric layer 5422 may be or include another one or more other dielectric materials. The fifth dielectric layer 5422 may be deposited using any appropriate deposition process, such as CVD, LPCVD, PECVD, or the like.

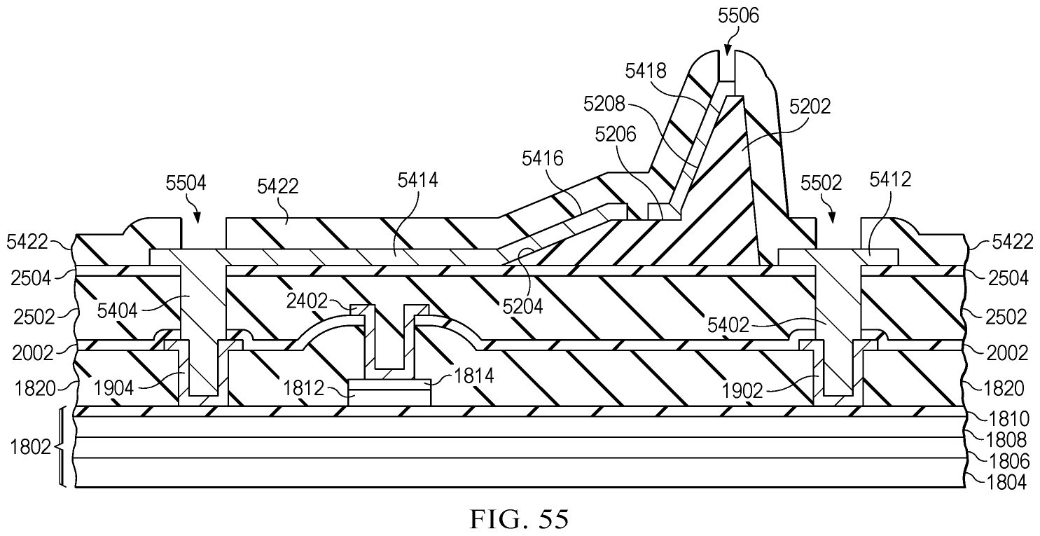

Referring to block 5012 of FIG. 50B and to FIG. 55, via openings 5502, 5504, 5506 are formed through fifth dielectric layer 5422. The via opening 5502 is formed through the fifth dielectric layer 5422 to the metal line 5412. The via opening 5504 is formed through the fifth dielectric layer 5422 to the metal line 5414. The via opening 5506 is formed through the fifth dielectric layer 5422 to the second field plate portion 5418. The via openings 5502, 5504, 5506 may be formed using appropriate photolithography and etch processes.

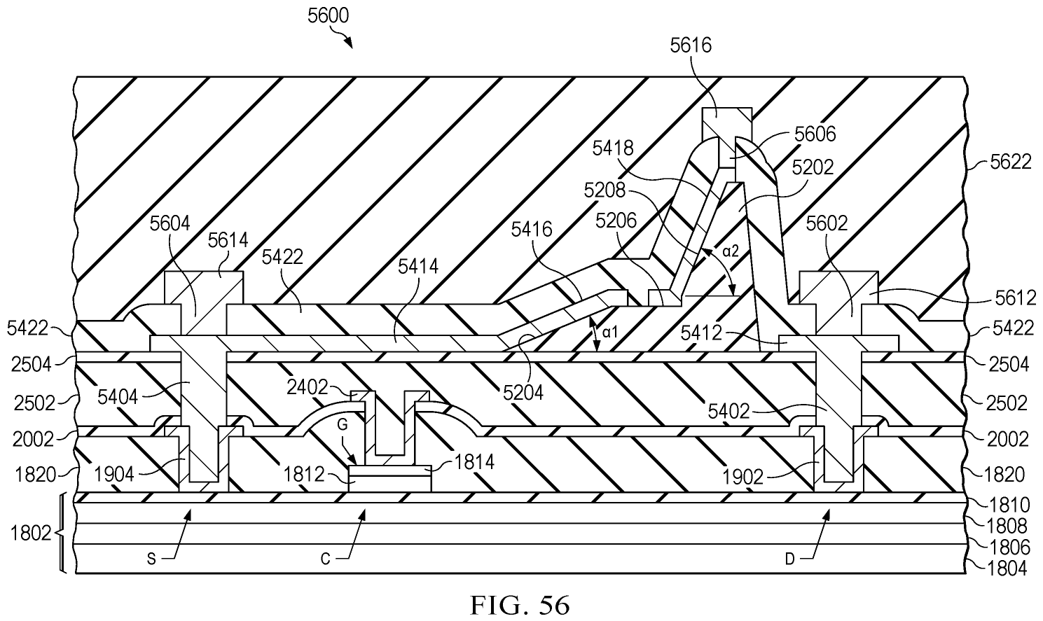

Referring to block 5014 of FIG. 50B and to FIG. 56, metal vias 5602, 5604, 5606 and metal lines 5612, 5614, 5616 are formed. The metal via 5602 is in the via opening 5502 and contacts the metal line 5412. The metal line 5612 is over and on the fifth dielectric layer 5422 and the metal via 5602, and the metal via 5602 extends from the metal line 5612 into the via opening 5502. The metal via 5604 is in the via opening 5504 and contacts the metal line 5414. The metal line 5614 is over and on the fifth dielectric layer 5422 and the metal via 5604, and the metal via 5604 extends from the metal line 5614 into the via opening 5504. The metal via 5606 is in the via opening 5506 and contacts the second field plate portion 5418. The metal line 5616 is over and on the fifth dielectric layer 5422 and the metal via 5606, and the metal via 5606 extends from the metal line 5616 into the via opening 5506. In the illustrated example, the metal lines 5612, 5614, 5616 are in a same metal layer (e.g., MET2 layer).

At block 5016, a sixth dielectric layer 5622 is formed over and on the fifth dielectric layer 5422 and the metal lines 5612, 5614, 5616. The sixth dielectric layer 5622 may be an ILD. In some examples, the sixth dielectric layer 5622 is or includes a silicon oxide-based material (such as a PSG or a TEOS oxide) or silicon nitride (SiN); although in other examples, the sixth dielectric layer 5622 may be or include another one or more other dielectric materials. The sixth dielectric layer 5622 may be deposited using any appropriate deposition process, such as CVD, LPCVD, PECVD, or the like. The sixth dielectric layer 5622 may be planarized, such as by a CMP.

FIG. 56 illustrates a cross-sectional view of the manufactured semiconductor device 5600. The semiconductor device 5600 includes a source S, a channel C, a drain D, and a gate G. The gate G is or includes the gate layer 1812, which is on an upper surface of the semiconductor substrate 1802 (e.g., an upper surface of the barrier layer 1810). The channel C is in the channel layer 1808 in the semiconductor substrate 1802 and underlying the gate G. The channel C is laterally between the drain D and the source S, which are also in the channel layer 1808. The drain metal contact 1902 is electrically coupled to the drain D, and the source metal contact 1904 is electrically coupled to the source S. The gate metal contact 2402 is electrically coupled to the gate G (e.g., the gate layer 1812). The gate G and gate metal contact 2402 are laterally between the drain metal contact 1902 and the source metal contact 1904. The semiconductor device 5600 includes a first field plate and a second field plate. The first field plate includes the first field plate portion 5416. The second field plate includes the second field plate portion 5418. The first field plate extends from the drain-side of the gate G towards the drain metal contact 1902. The field plate portions 5416, 5418 each have a respective uniform slope with respect to the upper surface of the semiconductor substrate 1802, as illustrated by respective slope angles α₁, α₂, α₃ with respect to respective planes parallel to the upper surface of the semiconductor substrate 1802. In some examples, the slope of the first field plate portion 5416 may be smaller than the slope of the second field plate portion 5418 (e.g., such that α₁<α₂). In some examples, the slope of the first field plate portion 5416 may be greater than the slope of the second field plate portion 5418 (e.g., such that α₁>α₂). The first field plate (e.g., the first field plate portion 5416) is electrically coupled through the metal line 5414, metal via 5404, and source metal contact 1904 to the source S (e.g., is a source-coupled field plate). A gap is between the first field plate portion 5416 and the second field plate portion 5418, e.g., at the separation surface 5206. The second field plate may be electrically coupled to another terminal, such as through routing in a metal layer(s) (e.g., metal line 5616). In some examples, rather than forming a second field plate, the second field plate portion 5418 may be electrically coupled to the first field plate portion 5416 to be another portion of the first field plate. For example, with the gap between the field plate portions 5416, 5418, routing in a metal layer(s) may electrically couple the second field plate portion 5418 to the first field plate portion 5416.

Although the various methods described above are described in the context of a gate-last process (e.g., a gate metal contact being formed after the source and drain metal contacts), various examples may implement a gate first process (e.g., a gate metal contact being formed before the source and drain metal contacts). Further, some examples may implement a self-aligned process for the gate metal contact and corresponding gate layer (and/or silicon layer). Various other modifications may be made.

In this description, the term “couple” may cover connections (e.g., through an electrical circuit (buffer driver, etc.) that may be monolithically integrated or co-packaged or an external part), communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

Although various examples have been described in detail, it should be understood that various changes, substitutions, and alterations can be made therein without departing from the scope defined by the appended claims.

What is claimed is:

1. A semiconductor device comprising:
a semiconductor substrate;
a gate on a surface of the semiconductor substrate;
a drain contact and a source contact on the semiconductor substrate; and
a field plate over the surface of the semiconductor substrate and extends from one side of the gate towards the drain contact, the field plate including multiple field plate portions, each of the multiple field plate portions having a uniform respective slope with respect to the surface, and the multiple field plate portions having different slopes.

2. The semiconductor device of claim 1, wherein the multiple field plate portions includes a first field plate portion having a first slope and a second field plate portion having a second slope, the first field plate portion is between the gate and the second field plate portion, and the first slope is smaller than the second slope.

3. The semiconductor device of claim 2, wherein the first field plate portion abuts a gate contact that electrically couples the gate.

4. The semiconductor device of claim 1, wherein the field plate is a first field plate and electrically coupled to a first terminal, and the semiconductor device further comprises a second field plate over the surface, the second field plate has a slope with respect to the surface, and the second field plate is electrically coupled to a second terminal.

5. The semiconductor device of claim 4, wherein the second field plate is between the first field plate and the drain contact.

6. The semiconductor device of claim 4, wherein the first terminal is electrically coupled to the gate, and the second terminal is electrically coupled to the source contact.

7. The semiconductor device of claim 4, wherein the first and second field plates are separated by a gap.

8. The semiconductor device of claim 1, further comprising:
a dielectric structure on the semiconductor substrate; and
an etch stop layer between the dielectric structure and the semiconductor substrate, wherein the field plate is on the dielectric structure.

9. The semiconductor device of claim 8, wherein the etch stop layer includes Aluminum oxide.

10. The semiconductor device of claim 1, wherein further comprising a Gallium nitride (GaN) layer on the semiconductor substrate, wherein the source contact and the drain contact are electrically coupled to a source and a drain, respectively, in the GaN layer, and the field plate is over the GaN layer.

11. A method comprising:
forming an etch stop layer on a surface of a semiconductor substrate of a semiconductor device, the semiconductor device including a gate, a drain contact, and a source contact on the surface;
forming one or more dielectric layers on the etch stop layer;
forming one or more photoresist layers on the dielectric layer between the gate and the drain contact;
patterning one or more photoresist layers with one or more grayscale masks to form first multiple slanted surfaces, each first slanted surface having a respective uniform slope, and the first slanted surfaces have different slopes;
etching the one or more dielectric layers to form second multiple slanted surfaces based on the first slanted surfaces of the one or more photoresist layers and to expose part of the etch stop layer; and
forming a field plate having multiple field plate portions on the second multiple slanted surfaces and on the exposed part of the etch stop layer between the gate and the drain contact, each of the multiple field plate portions having a uniform respective slope with respect to the surface of the semiconductor substrate, and the multiple field plates having different slopes.

12. The method of claim 11, wherein patterning the one or more photoresist layers with the one or more grayscale masks includes patterning a single photoresist layer with a single grayscale mask.

13. The method of claim 12, wherein the single grayscale mask includes a single constant pitch grayscale mask having a first region and a second region, the first region having a first fill factor distribution defining a first slope and the second region having a second fill factor distribution defining a second slope different from the first slope.

14. The method of claim 11, wherein patterning the one or more photoresist layers with the one or more grayscale masks includes:
patterning a first photoresist layer with a first grayscale mask to form a first one of the first multiple slanted surfaces;
patterning a first dielectric layer based on the patterned first photoresist layer to form a first one of the second multiple slanted surfaces;
forming a second dielectric layer on a first field plate portion and on the patterned first dielectric layer;
forming a second photoresist layer on the second dielectric layer;
patterning the second photoresist layer with a second grayscale mask to form a second one of the first multiple slanted surfaces; and
patterning the second dielectric layer based on the patterned second photoresist layer to form a second one of the second multiple slanted surfaces.

15. The method of claim 14, wherein the first grayscale mask includes a first constant pitch grayscale mask having a first fill factor distribution defining a first slope; and
wherein the second grayscale mask includes a second constant pitch grayscale mask having a second fill factor distribution defining a second slope different from the first slope.

16. The method of claim 11, further comprising forming a metal layer that electrically couples between the gate and the field plate.

17. The method of claim 11, further comprising forming a metal layer that electrically couples between the source contact and the field plate.

18. The method of claim 11, wherein the etch stop layer includes Aluminum oxide.

19. The method of claim 11, further comprising forming a Gallium nitride (GaN) layer on the semiconductor substrate, wherein the etch stop layer is formed on the GaN layer.

20. The method of claim 11, further comprising forming a gate layer on the semiconductor substrate, wherein the first and second multiple slanted surfaces are on a side of the gate layer.
